(19) United States
(12) Patent Application Publication
(10) Pub. No.: US 2023/0317717 A1
(43) Pub. Date: Oct. 5, 2023

(54) Multi-Device Stack Structure

(71) Applicant: Arm Limited, Cambridge (GB)

(72) Inventors: Amit Chhabra, Noida (IN); Brian Tracy Cline, Austin, TX (US); David Victor Pietromonaco, Cupertino, CA (US)

(21) Appl. No.: 17/708,915

(22) Filed: Mar. 30, 2022

(51) Int. Cl. H01L 27/06; H01L 27/092; H01L 29/423; H01L 29/06; H03K 19/20; G11C 11/412

(52) U.S. Cl. CPC H01L 27/0688; H01L 27/092; H01L 29/42392; H01L 29/0665; H03K 19/20; G11C 11/412

(57) ABSTRACT

Various implementations described herein are related to a device having a multi-device stack structure for use in multi-layered circuit architectures. The multi-device stack structure may have P-type transistors and N-type transistors that are arranged vertically in a multi-transistor stack configuration. In some implementations, the device may have a multi-device stack structure for use in multi-bit memory and/or logic architecture that is formed with complementary field effect transistor (CFET) technology.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In some modern circuit architecture, conventional transistor based devices use traditional layout techniques and thus suffer from low density design application that may typically cause unintended consequences in fabrication processes. Therefore, traditional layout techniques can be inefficient, density deficient and typically fail to provide sufficient means for implementing various different layout configurations. Thus, there exists a need to improve traditional layout techniques that allow for efficient device fabrication.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIG. 1 illustrates a diagram of bitcell architecture in accordance with various implementations described herein.

FIG. 2 illustrates a schematic diagram of multi-bit super-bitcell architecture in accordance with various implementations described herein.

FIGS. 3A-3D illustrate physical layout diagrams of super-bitcell architecture in accordance with various implementations described herein.

FIGS. 4A-4H illustrate various diagrams of multi-transistor stack architecture in multi-device stack configurations, such as, e.g., four-transistor (4T) stack configurations in accordance with various implementations described herein.

FIG. 5 illustrates a circuit diagram of bitline swap architecture in accordance with various implementations described herein.

FIGS. 6A-6D illustrate schematic and physical layout diagrams of multi-layer inverter architecture in accordance with various implementations described herein.

FIGS. 7A-7B illustrate schematic and physical layout diagrams of multi-layer NAND architecture in accordance with various implementations described herein.

FIGS. 8A-8B illustrate schematic and physical layout diagrams of multi-layer NOR architecture in accordance with various implementations described herein.

FIGS. 9A-9C illustrate schematic and physical layout diagrams of multi-layer AOI architecture in accordance with various implementations described herein.

### DETAILED DESCRIPTION

Various implementations described herein are directed to fabrication schemes and techniques for multi-device stack architecture in physical layout designs for various circuit related applications. In some implementations, the multi-device stack architecture may provide for logic cell applications in 3D-monolithic/sequential processes. In other implementations, the multi-device stack architecture may provide for memory cell (e.g., bitcell) applications in 3D-monolithic/sequential processes. Memory stores a value while logic performs some operation. The multi-device stack architecture may be manufactured in complementary field-effect-transistor (FET) technology. Moreover, various physical layout schemes and techniques described herein may provide for multi-transistor stacked device fabrication techniques for manufacturing on a single 3D-monolithic/sequential wafer. In some instances, monolithic means to create from the same underlying substrate, and sequential may refer to any sequential means, including bonding a fresh wafer or depositing/epitaxially-growing new semiconducting material on top.

In various implementations, there are multiple different ways of building device architecture for stacked transistors. For instance, one way is to build stacked transistors in a monolithic fashion, which refers to using a single wafer to create a stack of devices (e.g., nanosheets) from the same underlying substrate. In another instance, another way is to build stacked transistors in a sequential fashion, wherein one device stack is processed first, along with its contacts, vias, and interconnects, and is then, followed by another layer of device stack using a substantially thinned wafer or a freshly grown/deposited semiconductor layer. These multiple methods provide flexibility in managing various different devices in the stack in terms of threshold voltage, gate connections, etc. Therefore, stacked devices may be manufactured using various fabrication schemes and techniques described herein, including monolithic (monolithically formed stacks) and sequential (sequentially formed stacks).

Various implementations described herein are directed to fabrication schemes and techniques for building super logic cells, super memory cells, and super multi-bit bitcells (e.g., 2-bit bitcells), wherein each bit is formed in one complementary field effect transistor (CFET) multi-stack (e.g., 2-stack) configuration. In various implementations, the CFET cells may refer to logic cells, memory cells or static random access memory (SRAM) cells. In some implementations, the super logic cells, super memory cells, and super SRAM bitcells may be fabricated using stacked CFET technology in various circuit based structures and architectures. Accordingly, various implementations described herein may provide for area efficient standard cells in various multi-device stack (e.g., multi-device stack) configurations using stacked CFET technology. In various scenarios, memory stores a data value while logic performs an operation.

Various implementations described herein are directed to fabrication schemes and techniques for multi-transistor stack architectures in various physical layout designs for multi-device applications. For instance, various fabrication schemes and techniques described herein provide for various hybrid device stacking techniques for complementary field effect transistor (FET) technologies, and therefore, aspects of the present disclosure are associated with a novel device stack architecture arrangement for complementary FET (CFET) technologies and related applications. Also, the various fabrication schemes and techniques described herein provide a method of manufacture using hybrid technologies where multiple device stacks are fabricated together in a single monolithic semiconductor die. For instance, in some applications, N-over-P stacked devices and P-over-N stacked devices may be co-manufactured on a single wafer, and also, N-over-N stacked devices and P-over-P stacked devices refer to variants that may be simultaneously manufactured along with N-over-P stacked devices and/or P-over-N stacked devices in the same, single monolithic semiconductor die or wafer.

In some implementations, multi-transistor fabrication schemes and techniques described herein use novel technology that supports complementary FET (CFET) devices, wherein each device is fabricated with nano-sheets (NS) or Fin-FET (FF) that are used to form multiple devices in multi-transistor stacks within a single monolithic semiconductor die with multiple devices stacked on top of each other. The various fabrication schemes and techniques described herein provide for multiple complementary stack configurations, such as, e.g., an NN based structure having an N-over-N stack configuration and a PP based structure having a P-over-P stack configuration. In various instances, the gates for PFET devices and NFET devices may utilize common-gate and/or split-gate architecture in the multi-device stack configurations. Further, the multi-transistor fabrication schemes and techniques described herein also utilize technology that supports N-over-P devices along with P-over-N devices as additional stack configurations that may be fabricated with the N-over-N and P-over-P stack configurations within a single monolithic semiconductor die in various multi-transistor stack applications.

In some implementations, the various multi-transistor fabrication schemes and techniques described herein may provide for other types of multiple complementary stack configurations, such as, e.g., an NNNN based structure having an N-over-N-over-N-over-N stack configuration and a PPPP based structure having a P-over-P-over-P-over-P stack configuration. In various instances, the gates for PFET devices and NFET devices may utilize common-gate and/or split-gate architecture in the other types of multi-device stack configurations. Also, the multi-transistor fabrication schemes and techniques described herein utilize technology that supports N-over-P-over-P-over-N devices along with P-over-N-over-N-over-P devices as different vertical stack configurations. Moreover, various other supported multi-transistor structures may include P-over-P-over-N-over-N, N-over-N-over-P-over-P, P-over-N-over-P-over-N, and N-over-P-over-N-over-P stack configurations. In other implementations, the multi-device stack configurations are not specific to a stack of four, and as such, the multi-device cells may be created from any number of stacked devices.

In some implementations, the various multi-transistor fabrication schemes and techniques described herein may provide for other types of multiple stack configurations with any number of devices, such as, e.g., an N-only stack and/or a P-only stack For instance, as described herein, a precharge circuit may be formed with a P-only stack, wherein the P-only stack may include multiple transistors, such as, e.g., 2 or 3 or 4 or more transistors that may be built on top of each other in a multi-transistor stack structure. Also, various other circuits associated with memory architecture may have similar P-only/N-only stack configurations.

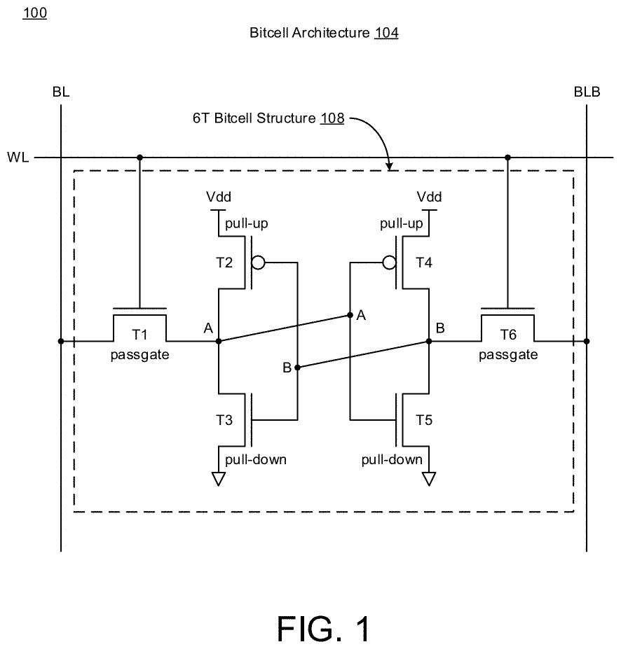

Various implementations of providing multi-transistor fabrication schemes and techniques for multi-device stack structures related to various physical layout designs for circuit architecture applications will now be described herein with reference to FIGS. 1, 2, 3A-3D, 4A-4H, 5, 6A-6D, 7A-7B, 8A-8B and 9A-9C.

FIG. 1 illustrates a diagram 100 of bitcell architecture 104 in accordance with various implementations described herein. In some scenarios, the bitcell architecture 104 may refer to a 6-transistor (6T) single-port bitcell architecture. In other scenarios, the bitcell architecture 104 may refer to any multi-transistor single-port and/or multi-port bitcell architectures, including, e.g., 2T, 4T and 8T, 10T, 12T, etc.

In some implementations, the bitcell architecture 104 may be implemented as a system or a device having various integrated circuit (IC) components that are arranged and coupled together as an assemblage or combination of parts that provide for physical circuit designs and various related structures. In some instances, a method of designing, providing and building the bitcell architecture 104 as an integrated system or device may involve use of various IC circuit components described herein so as to thereby implement fabrication schemes and techniques associated therewith. Also, the bitcell architecture 104 may be integrated with computing circuitry and related components on a single chip, and the bitcell architecture 104 may be implemented in various embedded systems for automotive, electronic, mobile, server and Internet-of-things (IoT) applications.

As shown in FIG. 1, the bitcell architecture 104 includes memory bitcell structure 108. In various implementations, the bitcell structure 108 may be configured as a six-transistor (6T) bitcell structure for various memory applications, including, e.g., static random access memory (SRAM) applications. In some scenarios, memory stores a data value while logic performs some operation.

In some implementations, the six-transistors (6T) of the 6T bitcell structure 108 may have multiple (e.g., 4) N-type metal-oxide-semiconductor (NMOS) transistors along with multiple (e.g., 2) P-type MOS (PMOS) transistors. In various scenarios, a passgate transistor (T1) is coupled between a first bitline (BL) and node (A), and another passgate transistor (T6) is coupled between a second bitline (BLB) and node (B). Also, the second bitline (BLB) is complementary to the first bitline (BL). The wordline (WL) may be coupled to gates of transistors (T1, T6) to access data stored in the latch formed with transistors (T2, T3, T4, T5) via the wordline (WL) and complementary bitlines (BL, BLB). Transistors (T2, T3) are coupled in series between the voltage supply (Vdd) and ground (Gnd or Vss), wherein node (A) is formed between pull-up transistor (T2) and pull-down transistor (T3). Also, transistors (T4, T5) are coupled in series between voltage supply (Vdd) and ground (Gnd or Vss), wherein node (B) is formed between pull-up transistor (T4) and pull-down transistor (T5). Transistors (T2, T3) are cross-coupled with transistors (T4, T5) such that node (A) is coupled to gates of transistors (T4, T5) and such that node (B) is coupled to gates of transistors (T2, T3). In various instances, transistors (T2, T4) may refer to P-type field-effect transistors (PFET), and further, transistors (T1, T3, T5, T6) may refer to N-type FET (NFET) transistors. However, various other configurations may be used to achieve similar results, characteristics and/or behavior.

The bitcell architecture 104 may be implemented with one or more core arrays of bitcells or memory cells, wherein each bitcell may be configured to store at least one data-bit value (e.g., data value related to a logical ‘0’ or ‘1’). The one or more core arrays may include any number of bitcells arranged in various configurations, such as, e.g., two-dimensional (2D) memory arrays having any number of columns and any number of rows of multiple bitcells, which may be arranged in a 2D grid pattern for read and write memory access. However, even though an SRAM bitcell structure is shown and described in FIG. 1, any other type of memory bitcell structure may be used to achieve similar results of the various bitcell fabrication techniques disclosed herein. In some scenarios, memory stores a data value while logic performs some operation.

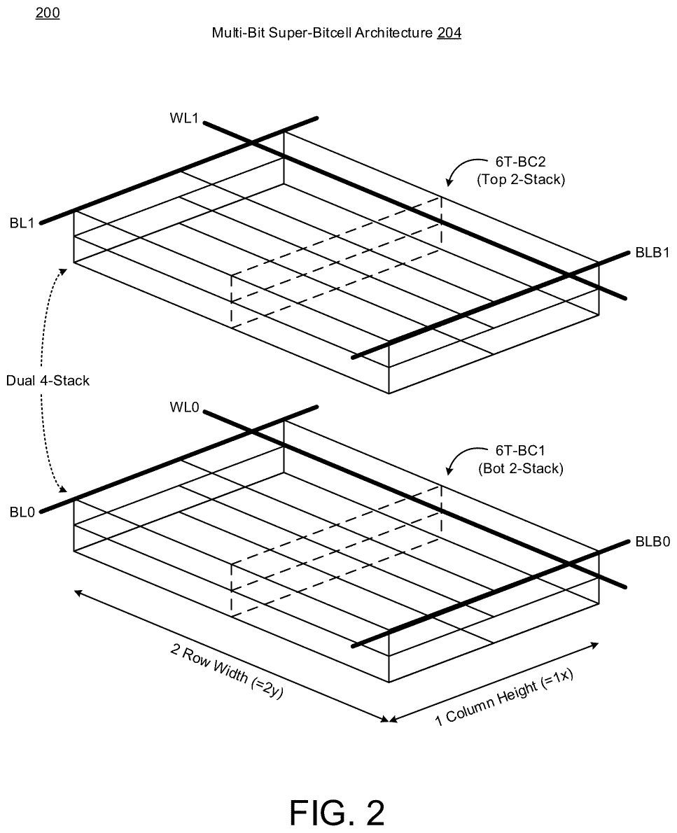

FIG. 2 illustrates a diagram 200 of a multi-bit super-bitcell architecture 204 in accordance with various implementations described herein. In various implementations, the multi-bit super-bitcell architecture 204 may refer to a two-bit (2-bit) super-bitcell having a multi-layer bitcell structure with a first bitcell and a second bitcell stacked together and arranged vertically in a multi-device stack, such as, e.g., a four-device stack.

In various implementations, the multi-bit super-bitcell architecture 204 may be implemented as a system or a device having various integrated circuit (IC) components that are arranged and coupled together as an assemblage or some combination of parts that provide for physical circuit designs and various related structures. In some instances, a method of designing, providing and fabricating the circuit architectures as an integrated system or device may involve use of various IC circuit components described herein so as to thereby implement fabrication schemes and techniques associated therewith. Also, the multi-bit super-bitcell architecture 204 may be integrated with computing circuitry and related components on a single chip, and also, the multi-bit super-bitcell architecture 204 may be implemented in various embedded systems for automotive, electronic, mobile, server and IoT applications, such as, e.g., remote sensor nodes.

As shown in FIG. 2, the multi-bit super-bitcell architecture 204 may comprise a multi-layer device having a multi-device stack structure for use in various memory based circuit architecture, such as, e.g., a multi-bit super-bitcell. In some instances, the multi-bit super-bitcell may refer to a 2-bit super-bitcell. The multi-device stack structure may have P-type transistors and N-type transistors that are arranged vertically in a multi-transistor stack configuration. The multi-layer device may include a first bitcell layer and a second bitcell layer, wherein the first bitcell layer may include a first multi-device stack with a first 6T bitcell (6T-BC1), wherein the second bitcell layer may include a second multi-device stack with a second 6T bitcell (6T-BC2). Thus, in some instances, the multi-layer device may refer to a dual multi-device stack structure having the second multi-device stack stacked on the first multi-device stack, wherein the second 6T bitcell (6T-BC2) stacked on top of the first 6T bitcell (6T-BC1). Also, in some instances, the row height refers to a single row height in the x-direction, and the column width refers to a 2 column width in the y-direction. Also, in some instances, the vertical z-direction refers to dual or double multi-device stack.

In some implementations, the multi-bit super-bitcell architecture 204 may have wordlines (WL) and bitlines (BL, BLB) formed in the multi-layered structure. For instance, the first bitcell layer may include at least one wordline (e.g., WL0) and at least one set of complementary bitlines (e.g., BL0, BLB0) that are coupled to the first 6T bitcell (6T-BC1) for accessing the 1-bit data stored therein in the first bitcell layer. Also, the second bitcell layer may include at least one wordline (e.g., WL1) and at least one set of complementary bitlines (e.g., BL1, BLB1) that are coupled to the second 6T bitcell (6T-BC2) for accessing 1-bit data stored therein in the second bitcell layer.

In some implementations, the multi-bit super-bitcell architecture 204 may have a multi-device stack structure that is formed in a single monolithic semiconductor die, and the P-type transistors and N-type transistors may be formed within the single monolithic semiconductor die. Also, in some instances, the memory based circuit architecture may be formed as a three-dimensional (3D) monolithic or sequential circuit architecture. Also, as described in various implementations herein, the multi-bit super-bitcell architecture 204 may be formed with the multi-device stack structure having the memory based circuit architecture that is used for at least one of multi-bit bitcells, inverters, NAND gates, NOR gates and AND-OR-Invert (AOI) gates. Moreover, various other related memory based circuit architectures may be formed in a similar manner without departing from the scope of the present disclosure.

In some implementations, the multi-bit super-bitcell architecture 204 may have a multi-device stack structure formed with a multi-transistor stack configuration including various multi-device stack configurations, such as, e.g., a four-device stack configuration of P-type transistors and N-type transistors. Also, in various implementations, the P-type transistors may include P-type field-effect transistors (PFETs), and in addition, the N-type transistors may include N-type field-effect transistors (NFETs). Additional scope related to these features and characteristics are described in greater detail herein below.

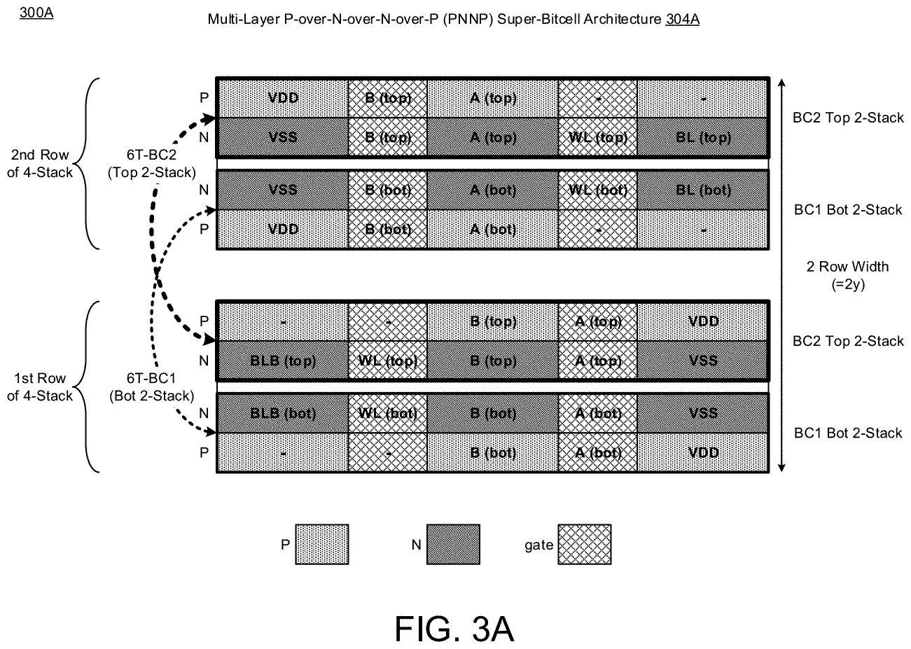

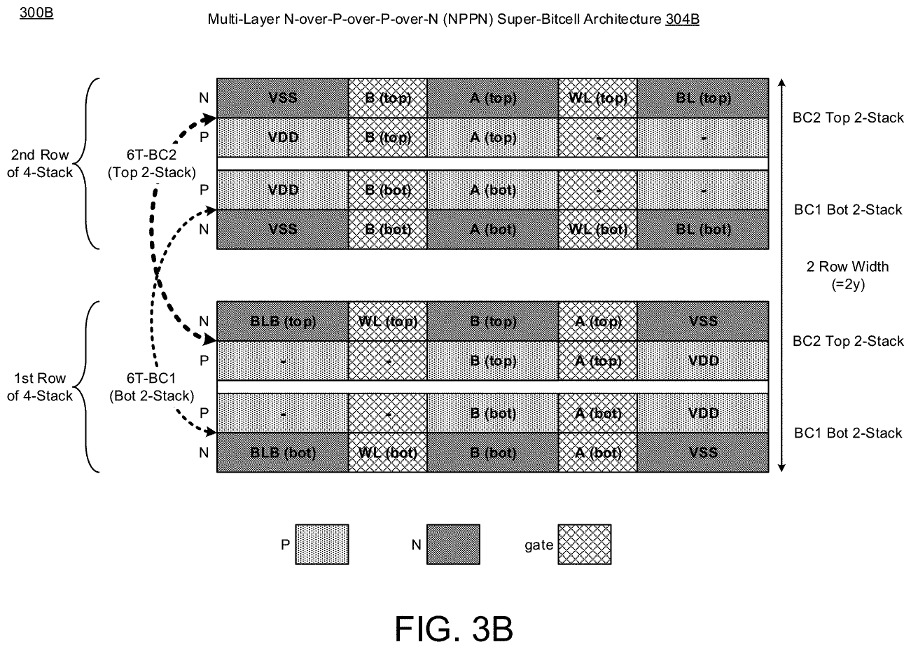

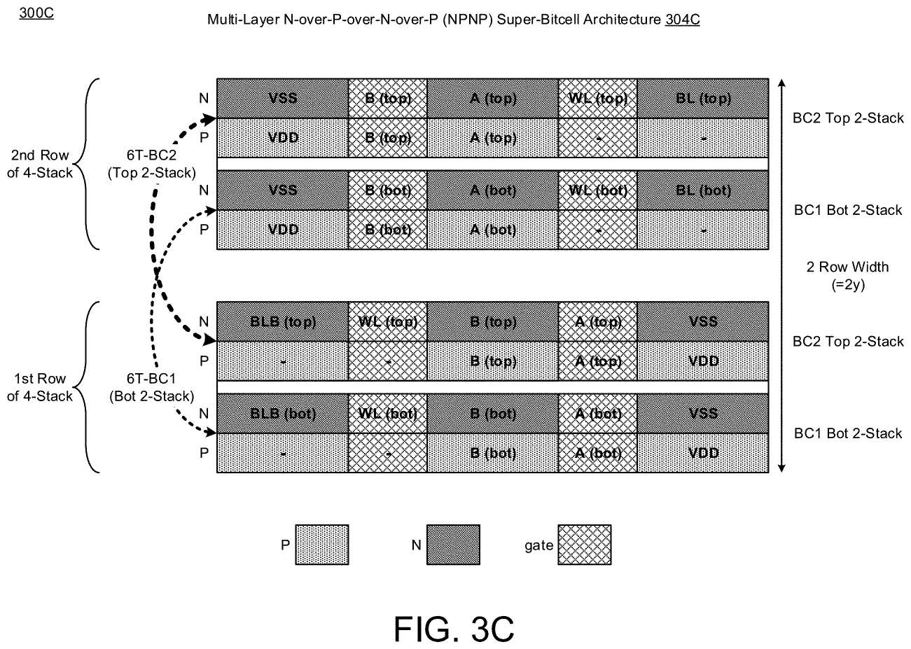

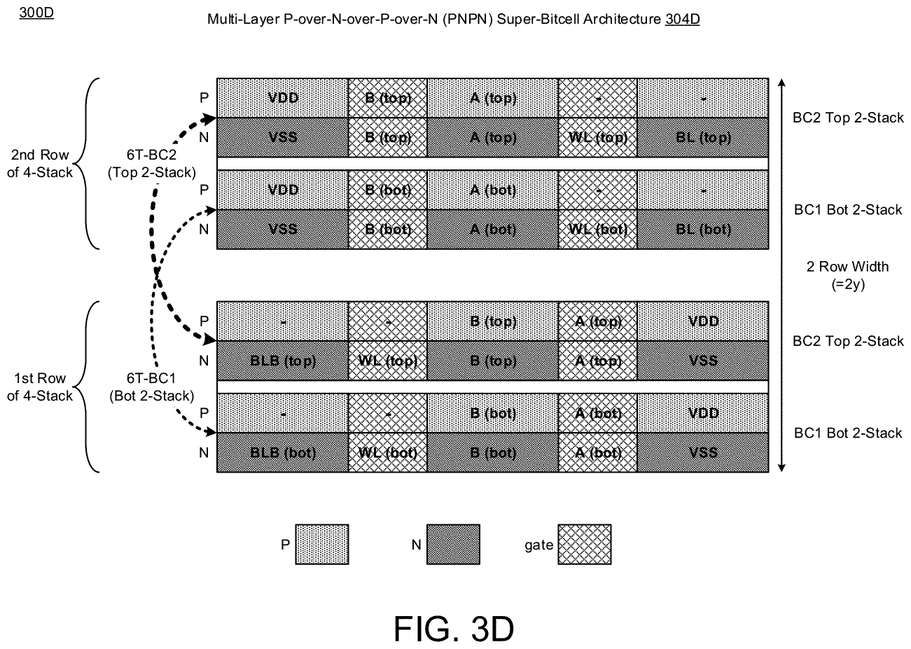

FIGS. 3A-3D illustrate physical layout cross-sections of multi-layered super-bitcell architectures in accordance with various implementations described herein. FIGS. 3A-3D show 2-layer architectures; however, multi-layered architectures described herein may extend beyond 2-layer architectures. In particular, FIG. 3A shows a multi-layer P-over-N-over-N-over-P (PNNP) super-bitcell architecture 304A, FIG. 3B shows another multi-layer N-over-P-over-P-over-N(NPPN) super-bitcell architecture 304B, FIG. 3C shows another multi-layer N-over-P-over-N-over-P (NPNP) super-bitcell architecture 304C, and FIG. 3D shows another multi-layer P-over-N-over-P-over-N (PNPN) super-bitcell architecture 304D. The diagrams shown in FIGS. 3A-3D are described in reference to the diagrams shown in FIGS. 1-2.

As shown in FIG. 3A, the multi-bit super-bitcell architecture 304A may refer to a multi-layer device having a multi-stack device structure for use in various memory based circuit architecture, such as, e.g., a multi-bit super-bitcell. In some instances, the multi-bit super-bitcell may refer to a 2-bit super-bitcell. The multi-stack device structure may have P-type transistors and N-type transistors that are arranged vertically in a multi-transistor stack configuration. The multi-layer device may have the first bitcell layer and the second bitcell layer, wherein the first bitcell layer may include a first 6T bitcell (6T-BC1), wherein the second bitcell layer may include a second 6T bitcell (6T-BC2).

In some implementations, the multi-bit super-bitcell architecture 304A may have the multi-layered P-over-N-over-N-over-P (PNNP) multi-transistor stack configuration. As shown in FIG. 3A, the first bitcell layer has two rows of bottom N-over-P multi-transistor stack configuration (6T-BC1), and the second bitcell layer has two rows of top P-over-N multi-transistor stack configuration. (6T-BC2).

In some scenarios, from left-to-right, the first bitcell row includes a bottom (bot) P-layer with an uncoupled (−) P-region, an uncoupled (−) gate region, another P-region coupled to node (B) of bottom (bot) bitcell (6T-BC1), another gate region coupled to node (A) of bottom (bot) bitcell (6T-BC1), and another P-region coupled to supply voltage (VDD). Also, from left-to-right, the first bitcell row includes a bottom (bot) N-layer with an N-region coupled to a bottom (bot) bitline (BLB), a gate region coupled to a bottom (bot) wordline (WL0), another N-region coupled to node (B) of bottom (bot) bitcell (6T-BC1), another gate region coupled to node (A) of bottom (bot) bitcell (6T-BC1), and another N-region coupled to ground (VSS). Also, from left-to-right, the first bitcell row includes a top N-layer with an N-region coupled to a top bitline (BLB), a gate region coupled to a top wordline (WL1), another N-region coupled to node (B) of top bitcell (6T-BC2), another gate region coupled to node (A) of top bitcell (6T-BC2), and another N-region coupled to ground (VSS). Moreover, from left-to-right, the first bitcell row includes a top P-layer with an uncoupled (−) P-region, an uncoupled (−) gate region, another P-region coupled to node (B) of top bitcell (6T-BC2), another gate region coupled to node (A) of top bitcell (6T-BC2), and another P-region coupled to supply voltage (VDD). In various instances, the gate region may be formed with any type of gate material, such as, e.g., various types of metal material and/or semiconductor material that may be used to form the gate region.

In some scenarios, from left-to-right, the second bitcell row includes a bottom (bot) P-layer with a P-region coupled to supply voltage (VDD), a gate region coupled to node (B) of bottom (bot) bitcell (6T-BC1), another P-region coupled to node (A) of bottom (bot) bitcell (6T-BC1), an uncoupled (−) gate region, and an uncoupled (−) P-region. Also, from left-to-right, the second bitcell row includes a bottom (bot) N-layer with an N-region coupled to ground (VSS), a gate region coupled to node (B) of bottom (bot) bitcell (6T-BC1), another N-region coupled to node (A) of bottom (bot) bitcell (6T-BC1), another gate region coupled to a bottom (bot) wordline (WL0), and another N-region coupled to a bottom (bot) bitline (BL). Also, from left-to-right, the second bitcell row includes a top N-layer with an N-region coupled to ground (VSS), a gate region coupled to node (B) of top bitcell (6T-BC2), another N-region coupled to node (A) of top bitcell (6T-BC2), another gate region coupled to a top wordline (WL1), and another N-region coupled to a top bitline (BL). Moreover, from left-to-right, the second bitcell row includes a top P-layer with a P-region coupled to supply voltage (VDD), a gate region coupled to node (B) of top bitcell (6T-BC2), another P-region coupled to node (A) of top bitcell (6T-BC2), an uncoupled (−) gate region, and an uncoupled (−) P-region.

As shown in FIG. 3B, the multi-bit super-bitcell architecture 304B may refer to a multi-layer device having a multi-stack device structure for use in various memory based circuit architecture, such as, e.g., a multi-bit super-bitcell. In some instances, the multi-bit super-bitcell may refer to a 2-bit super-bitcell. The multi-stack device structure may have P-type transistors and N-type transistors that are arranged vertically in a multi-transistor stack configuration. The multi-layer device may have the first bitcell layer and the second bitcell layer, wherein the first bitcell layer may include a first multi-device stack with a first 6T bitcell (6T-BC1), wherein the second bitcell layer may include a second multi-device stack with a second 6T bitcell (6T-BC2).

In some implementations, the multi-bit super-bitcell architecture 304B may have the multi-layered N-over-P-over-P-over-N(NPPN) multi-transistor stack configuration. As shown in FIG. 3B, the first bitcell layer has first 4-stack device (6T-BC1) arranged in the NPPN multi-transistor stack configuration, and the second bitcell layer has second 4-stack device (6T-BC2) arranged in the NPPN multi-transistor stack configuration.

In this instance, the N-layers and the P-layers are swapped when compared to the multi-transistor stack configuration in FIG. 3A. For instance, as shown in FIG. 3B, the N-layers and the P-layers of the first bitcell layer of 6T-BC1 are swapped from N-over-P to P-over-N in the bottom (bot) region, and the N-layers and the P-layers of the first bitcell layer of 6T-BC1 are swapped from P-over-N to N-over-P in the top region. Further, as shown in FIG. 3B, the N-layers and the P-layers of the second bitcell layer of 6T-BC2 are swapped from N-over-P to P-over-N in the bottom (bot) region, and the N-layers and the P-layers of the second bitcell layer of 6T-BC2 are swapped from P-over-N to N-over-P in the top region.

As shown in FIG. 3C, the multi-bit super-bitcell architecture 304C may refer to a multi-layer device having a multi-stack device structure for use in various memory based circuit architecture, such as, e.g., a multi-bit super-bitcell. In some instances, the multi-bit super-bitcell may refer to a 2-bit super-bitcell. The multi-stack device structure may have P-type transistors and N-type transistors that are arranged vertically in a multi-transistor stack configuration. The multi-layer device may have the first bitcell layer and the second bitcell layer, wherein the first bitcell layer may include a first multi-device stack with a first 6T bitcell (6T-BC1), wherein the second bitcell layer may include a second multi-device stack with a second 6T bitcell (6T-BC2).

In some implementations, the multi-bit super-bitcell architecture 304C has the multi-layered N-over-P-over-N-over-P (NPNP) multi-transistor stack configuration. Also, as shown in FIG. 3C, the first bitcell layer has first 4-stack device (6T-BC1) arranged in the NPNP multi-transistor stack configuration, and the second bitcell layer has second 4-stack device (6T-BC2) arranged in the NPNP multi-transistor stack configuration.

In this instance, the top N-layers and the top P-layers may be swapped when compared to the multi-transistor stack configuration in FIG. 3A. For instance, as shown in FIG. 3C, the top N-layers and the top P-layers of the first bitcell layer of 6T-BC1 are swapped from P-over-N to N-over-P, and the bottom (bot) N-layers and the bottom (bot) P-layers of the first bitcell layer of 6T-BC1 remain the same. Also, as shown in FIG. 3C, the top N-layers and the top P-layers of the second bitcell layer of 6T-BC2 are swapped from P-over-N to N-over-P, and the bottom (bot) N-layers and the bottom (bot) P-layers of the second bitcell layer of 6T-BC2 remain the same.

As shown in FIG. 3D, the multi-bit super-bitcell architecture 304D may refer to a multi-layer device having a multi-stack device structure for use in various memory based circuit architecture, such as, e.g., a multi-bit super-bitcell. In some instances, the multi-bit super-bitcell may refer to a 2-bit super-bitcell. The multi-stack device structure may have P-type transistors and N-type transistors that are arranged vertically in a multi-transistor stack configuration. The multi-layer device may have the first bitcell layer and the second bitcell layer, wherein the first bitcell layer may include a first multi-device stack with a first 6T bitcell (6T-BC1), wherein the second bitcell layer may include a second multi-device stack with a second 6T bitcell (6T-BC2).

In some implementations, the multi-bit super-bitcell architecture 304D has the multi-layered P-over-N-over-P-over-N (PNPN) multi-transistor stack configuration. Also, as shown in FIG. 3D, the first bitcell layer has first 4-stack device (6T-BC1) arranged in the PNPN multi-transistor stack configuration, and the second bitcell layer has second 4-stack device (6T-BC2) arranged in the PNPN multi-transistor stack configuration.

In this instance, the bottom (bot) N-layers and the bottom (bot) P-layers may be swapped when compared to the multi-transistor stack configuration in FIG. 3A. For instance, as shown in FIG. 3D, the bottom (bot) N-layers and the bottom (bot) P-layers of the first bitcell layer of 6T-BC1 are swapped from N-over-P to P-over-N, and the top N-layers and the top P-layers of the first bitcell layer of 6T-BC1 remain the same. Also, as shown in FIG. 3D, the bottom (bot) N-layers and the bottom (bot) P-layers of the second bitcell layer of 6T-BC2 are swapped from N-over-P to P-over-N, and the top N-layers and the top P-layers of the second bitcell layer of 6T-BC2 remain the same.

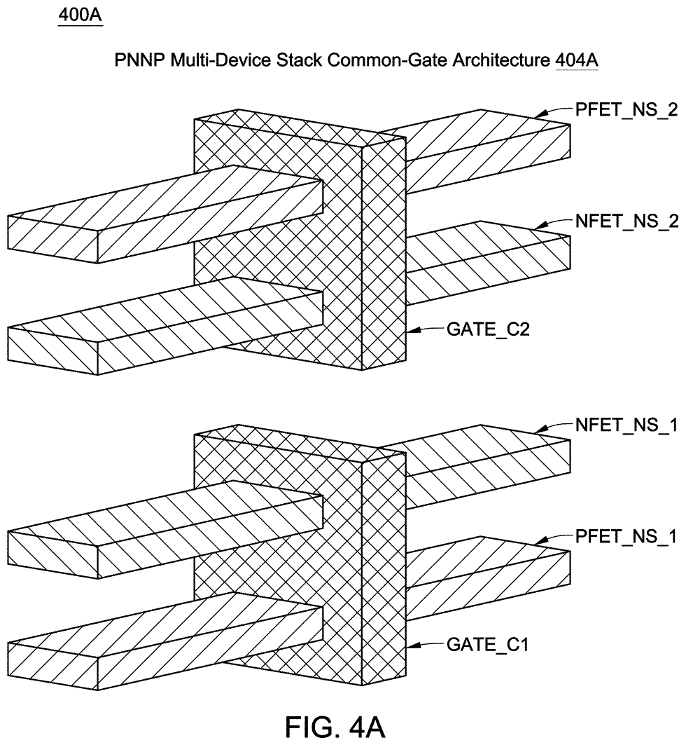

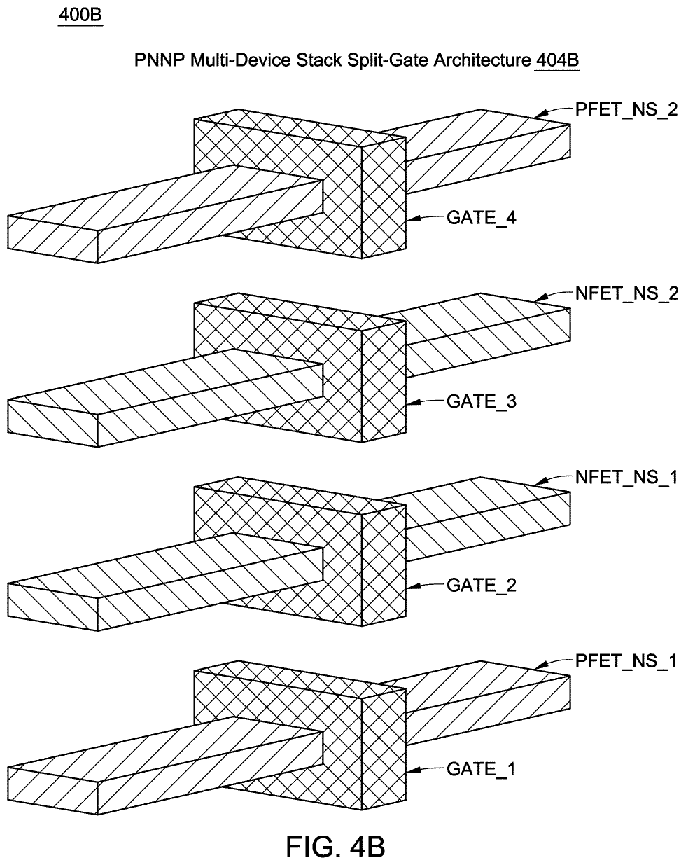

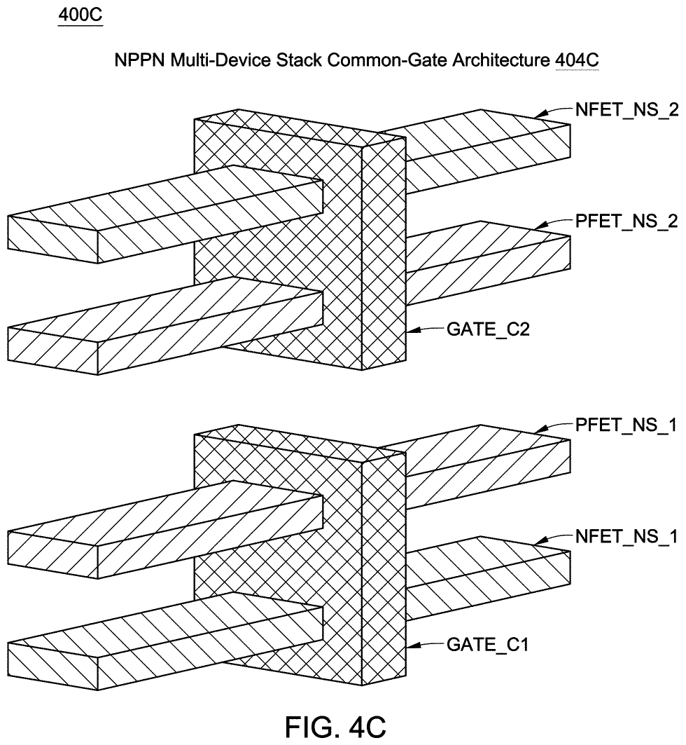

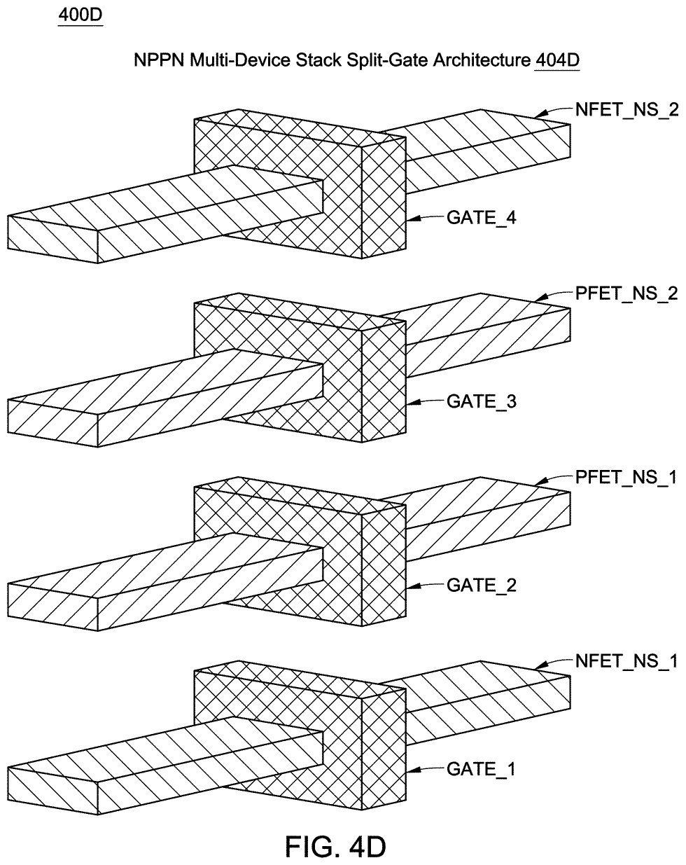

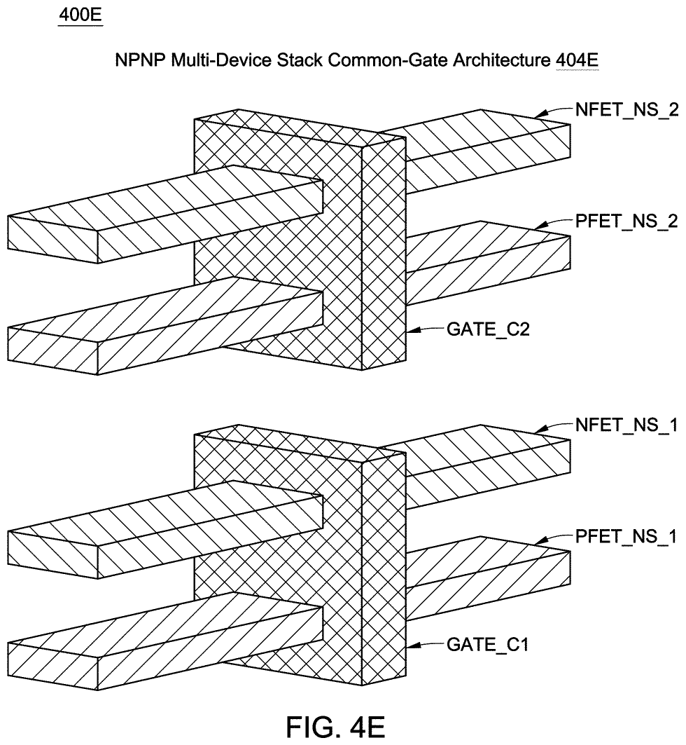

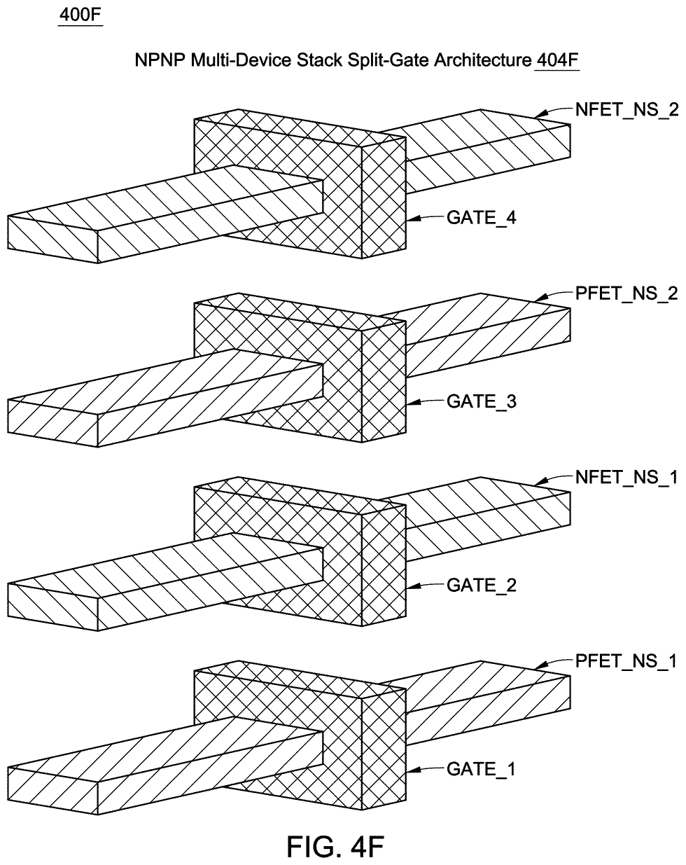

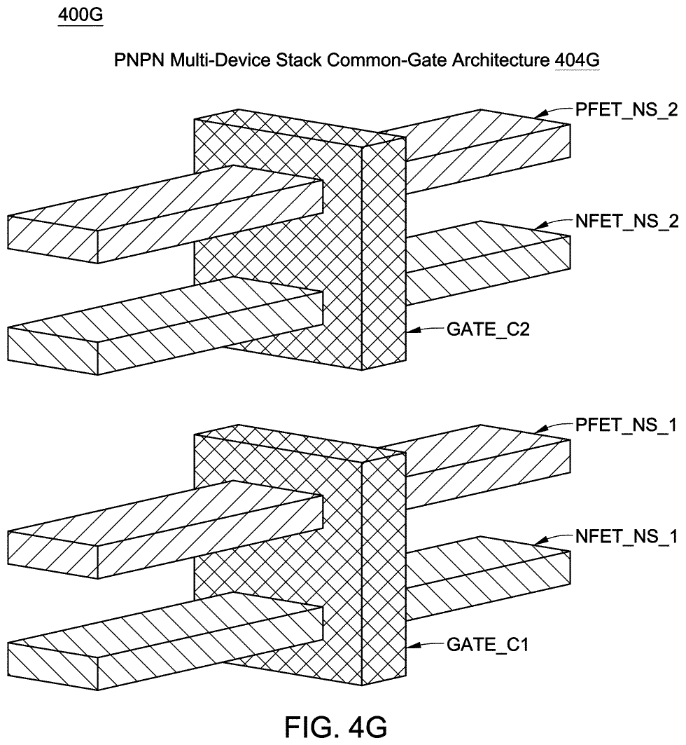

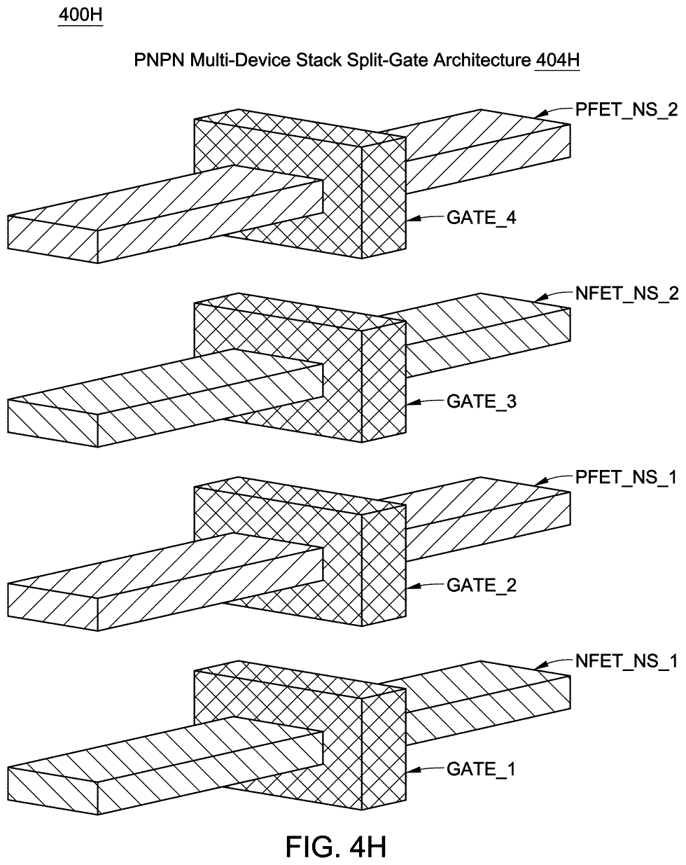

FIGS. 4A-4H illustrate various diagrams of multi-transistor stack architecture in multi-device stack configurations, such as, e.g., 4T stack configurations, in accordance with various implementations described herein. In particular, FIGS. 4A, 4C, 4E and 4G show various multi-layer diagrams of multi-transistor stack structures with dual-common-gate architecture, and also, FIGS. 4B, 4D, 4F and 4H show various multi-layer diagrams of the multi-transistor stack structures with split-gate architecture. In various instances, the multi-device stack configurations may be referred to as gate-all-around devices in a manner as shown in reference to FIGS. 4A-4H.

As shown in FIG. 4A, the P-over-N-over-N-over-P (PNNP) dual-common-gate related transistor architecture 404A may include multiple transistors (e.g., 2 PFET devices and 2 NFET devices) that are arranged in a multi-transistor stack configuration. In some instances, a first PFET may be formed in a first PFET nano-sheet (PFET_NS_1), and a second PFET may be formed in a second PFET nano-sheet (PFET_NS_2), which may be disposed vertically in a single stack. Also, a first NFET may be formed in a first NFET nano-sheet (NFET_NS_1), and a second NFET may be formed in a second NFET nano-sheet (NFET_NS_2), which may be disposed vertically in the same single stack with the PFET devices. The common-gate architecture 404A may include multiple common-gates (e.g., dual poly gate lines) coupled to the multiple transistors. In some instances, a first common-gate (GATE_C1) may be coupled to PFET_NS_1 device and NFETNS_1 device, and also, a second common-gate (GATE_C2) may be coupled to the NFET_NS_2 device and PFET_NS_2 device. This multi-device stack arrangement provides the PNNP stack configuration as a four-FET stacked device that is manufactured and/or formed in a same single monolithic semiconductor die. Further, in some instances, the pair of N-type devices may be disposed between the pair of P-type devices in the multi-transistor stack architecture 404A along with the dual-common-gate structure.

As shown in FIG. 4B, the P-over-N-over-N-over-P (PNNP) split-gate related transistor architecture 404B may include multiple transistors (e.g., 2 PFET devices and 2 NFET devices) arranged in a multi-transistor stack configuration. In various instances, a first PFET may be formed in a first PFET nano-sheet (PFETNS_1), and a second PFET may be formed in a second PFET nano-sheet (PFET_NS_2), which may be disposed vertically in a single stack. In addition, a first NFET may be formed in a first NFET nano-sheet (NFET_NS_1), and a second NFET may be formed in a second NFET nano-sheet (NFET_NS_2), which may be disposed vertically in the same single stack along with the two PFET devices. The split-gate architecture 404B may include multiple split-gates (e.g., multiple poly gate lines) coupled to the multiple transistors. In some instances, a first gate (GATE_1) may be coupled to the PFETNS_1 device, a second gate (GATE_2) may be coupled to the NFETNS_1 device, a third gate (GATE_3) may be coupled to the NFET_NS_2 device, and a fourth gate (GATE_4) may be coupled to the PFET_NS_2 device. This multi-device stack arrangement provides the PNNP stack configuration as a four-FET stacked device that is manufactured and/or formed in a same single monolithic semiconductor die. Also, in some instances, the pair of N-type devices may be disposed between the pair of P-type devices in the multi-transistor stack architecture 404B along with the quad-split-gate structure.

As shown in FIG. 4C, the N-over-P-over-P-over-N(NPPN) dual-common-gate related transistor architecture 404C may include multiple transistors (e.g., 2 NFET devices and 2 PFET devices) that are arranged in a multi-transistor stack configuration. In some instances, a first NFET may be formed in a first NFET nano-sheet (NFET_NS_1), and a second NFET may be formed in a second NFET nano-sheet (NFET_NS_2), which may be disposed vertically in a single stack. Further, a first PFET may be formed in a first PFET nano-sheet (PFET_NS_1), and a second PFET may be formed in a second PFET nano-sheet (PFET_NS_2), which may be disposed vertically in the same single stack with the NFET devices. The common-gate architecture 404C may include multiple common-gates (e.g., dual poly gate lines) coupled to the multiple transistors. In some instances, a first common-gate (GATE_C1) may be coupled to NFETNS_1 device and PFETNS_1 device, and also, a second common-gate (GATE_C2) may be coupled to the PFET_NS_2 device and NFET_NS_2 device. This multi-device stack arrangement provides the NPPN stack configuration as a four-FET stacked device that is manufactured and/or formed in a same single monolithic semiconductor die. Further, in some instances, the pair of P-type devices may be disposed between the pair of N-type devices in the multi-transistor stack architecture 404C along with the dual-common-gate structure.

As shown in FIG. 4D, the N-over-P-over-P-over-N(NPPN) split-gate related transistor architecture 404D may include multiple transistors (e.g., 2 NFET devices and 2 PFET devices) arranged in a multi-transistor stack configuration. In various instances, a first NFET may be formed in a first NFET nano-sheet (NFETNS_1), and a second NFET may be formed in a second NFET nano-sheet (NFET_NS_2), which may be disposed vertically in a single stack. In addition, a first PFET may be formed in a first PFET nano-sheet (PFET_NS_1), and a second PFET may be formed in a second PFET nano-sheet (PFET_NS_2), which may be disposed vertically in the same single stack along with the two NFET devices. The split-gate architecture 404D may include multiple split-gates (e.g., multiple poly gate lines) coupled to the multiple transistors. In some instances, a first gate (GATE_1) may be coupled to the NFET_NS_1 device, a second gate (GATE_2) may be coupled to the PFET_NS_1 device, a third gate (GATE_3) may be coupled to the PFET_NS_2 device, and a fourth gate (GATE_4) may be coupled to the NFET_NS_2 device. This multi-device stack arrangement provides the NPPN stack configuration as a four-FET stacked device that is manufactured and/or formed in a same single monolithic semiconductor die. Also, in some instances, the pair of P-type devices may be disposed between the pair of N-type devices in the multi-transistor stack architecture 404D along with the quad-split-gate structure.

In some implementations, based on the foregoing description provided herein above in reference to FIGS. 4A-4D, the various multi-transistor fabrication schemes and techniques described herein may be utilized to implement various other multi-transistor stack configurations as shown in FIGS. 4E-4H.

As shown in FIG. 4E, an NPNP common-gate related transistor architecture 404E may provide for multiple transistors (e.g., 2 NFET devices and 2 PFET devices) arranged in a multi-transistor stack configuration. In some instances, the NPNP transistor architecture 404E may refer to an N-over-P-over-N-over-P stack structure. In addition, as shown in FIG. 4F, a NPNP split-gate related transistor architecture 404F may include multiple transistors (e.g., 2 NFET devices and 2 PFET devices) arranged in another multi-transistor stack configuration. In other instances, the NPNP transistor architectures 404E, 404F may refer to a PNPN stack structure (when layered from bottom-up).

As shown in FIG. 4G, a PNPN common-gate related transistor architecture 404G may provide for multiple transistors (e.g., 2 NFET devices and 2 PFET devices) arranged in a multi-transistor stack configuration. In some instances, the PNPN transistor architecture 404G may refer to a P-over-N-over-P-over-N stack structure. In addition, as shown in FIG. 4H, a PNPN split-gate related transistor architecture 404H may include multiple transistors (e.g., 2 NFET devices and 2 PFET devices) arranged in another multi-transistor stack configuration. In other instances, the PNPN transistor architectures 404G, 404H may refer to an NPNP stack structure (when layered from bottom-up).

The various implementations described herein refer to fabrication schemes and techniques that provide for various multi-transistor stack architectures in various physical layout designs for multi-transistor stack applications. In various instances, FIGS. 4A-4H provide for a four-transistor (e.g., 4T) stack architecture in the same, single vertical stack in common-gate and split-gate formations. Also, the various implementations described herein refer to a method for manufacturing, and/or causing to be manufactured, multiple devices packaged within a single semiconductor die.

In various implementations, the multi-transistor stack may have four transistors (e.g., 4T) arranged vertically in a four-transistor stack. The four-transistor stack may refer to various different configurations, such as, e.g., PNNP stack configuration, NPPN stack configuration, NPNP stack configuration and PNPN stack configuration. Also, in various implementations, the transistors may refer to field-effect transistor (FET) devices including N-type FET (NFET) devices and P-type FET (PFET) devices.

Various implementations described herein may provide for multi-device stacked circuit architecture, such as, e.g., bitcells, inverters, NAND gates, NOR gates, and AOI gates, in 3D monolithic designs. For instance, various circuit architectures may be provided that have a multi-transistor stacked structure for use in physical circuit related architecture. The multi-transistor structure may include a multi-transistor stack of N-type transistors and P-type transistors that are arranged in a multi-device stack configuration, and also, the physical layout of multi-device stack configurations may provide for various circuit applications for use in standard computing circuitry.

In some implementations, the multi-transistor structure may be formed within a single monolithic semiconductor die, and the multi-transistor stack of N-type transistors may be formed within the single monolithic semiconductor die, and the circuit architecture may refer to a three-dimensional (3D) circuit architecture. The circuit architecture may be used in various applications, such as, e.g., at least one of bitcells, inverters, NAND gates, NOR gates, and AOI gates. In various physical layout scenarios, the multi-device stack configuration may have a four-device stack configuration of N-type transistors and P-type transistors that are arranged in a P-over-N-over-N-over-P (PNNP) stack configuration, an N-over-P-over-P-over-N(NPPN) stack configuration, an N-over-P-over-N-over-P (NPNP) stack configuration, or a P-over-N-over-P-over-N (PNPN) stack configuration. Moreover, the N-type transistors may refer to N-type field-effect transistors (NFETs), and the P-type transistors may refer to P-type field-effect transistors (PFETs).

In various implementations, in reference to FIGS. 1-2, 3A-3D and 4A-4H, the bitcell architecture may refer to a device having a multi-device stack structure for use in two-bit standard memory cell architecture formed with complementary field effect transistor (CFET) technology, wherein the multi-device stack structure may have P-type transistors and N-type transistors that are arranged vertically in a four-transistor stack configuration. Also, the multi-device stack structure may be formed in a single monolithic semiconductor die, and the P-type transistors and N-type transistors are formed within the single monolithic semiconductor die, and the two-bit standard cell architecture refers to a three-dimensional (3D) monolithic circuit architecture. Also, the two-bit standard cell architecture may refer to a two-bit (2-bit) memory cell for use in random access memory (RAM) applications, and the four-transistor stack configuration includes a four-device stack configuration of P-type transistors and N-type transistors. The P-type transistors may refer to PFET devices, and the N-type transistors may refer to NFET devices. Moreover, in various implementations, the four-transistor stack configuration may refer to a four-device stack of P-type transistors and N-type transistors arranged in a PNNP stack configuration, NPPN stack configuration, PNPN stack configuration, or NPNP stack configuration.

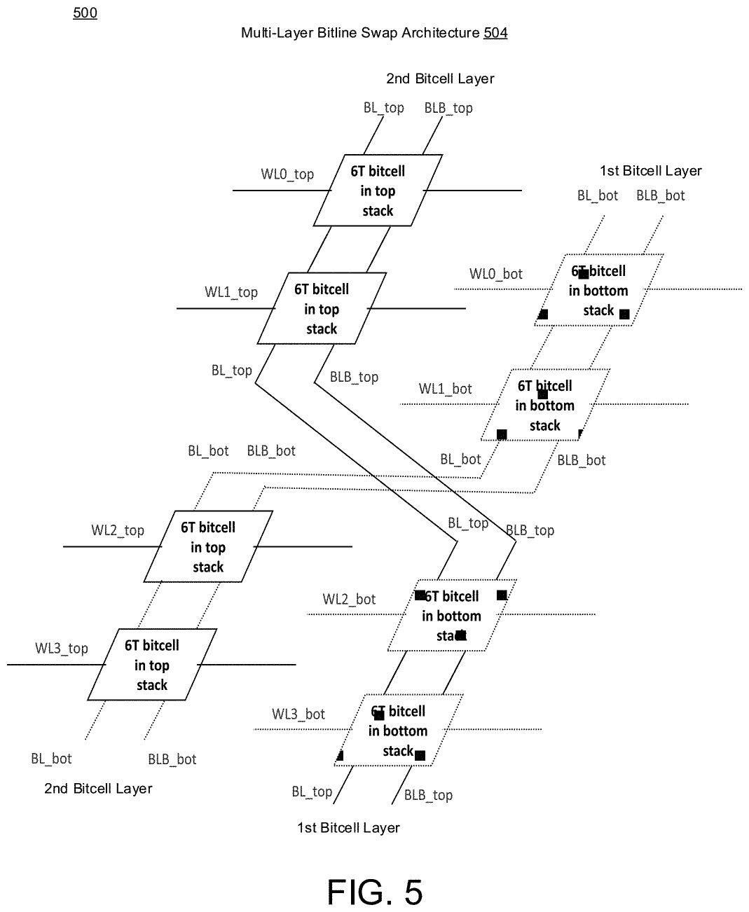

FIG. 5 illustrates a circuit diagram 500 of multi-layer bitline swap architecture 504 in accordance with various implementations described herein.

As shown in FIG. 5, the multi-layer bitline swap architecture 504 may include multiple bitcell layers including the first bitcell layer and the second bitcell layer, wherein the second bitcell layer is disposed to overlie on the first bitcell layer. The first bitcell layer may include multiple 6T bitcells in the top stack structure, and the second bitcell layer may include multiple 6T bitcells in the bottom (bot) stack structure. Also, the top stack structure may have complementary bitlines (BL_top, BLB_top) and wordlines (WL0_top, WL1_top, WL2_top, WL3_top) coupled to corresponding 6T bitcells in the top stack, and the bottom (bot) stack structure may have complementary bitlines (BL_bot, BLB_bot) and wordlines (WL0_bot, WL1_bot, WL2_bot, WL3_bot) coupled to corresponding 6T bitcells in the bottom (bot) stack. Moreover, as shown in FIG. 5, in some implementations, the multi-layer bitline swap architecture 504 may be configured to swap bitlines (BL_top, BLB_top) from the top stack with bitlines (BL_bot, BLB_top) from the bottom (bot) stack.

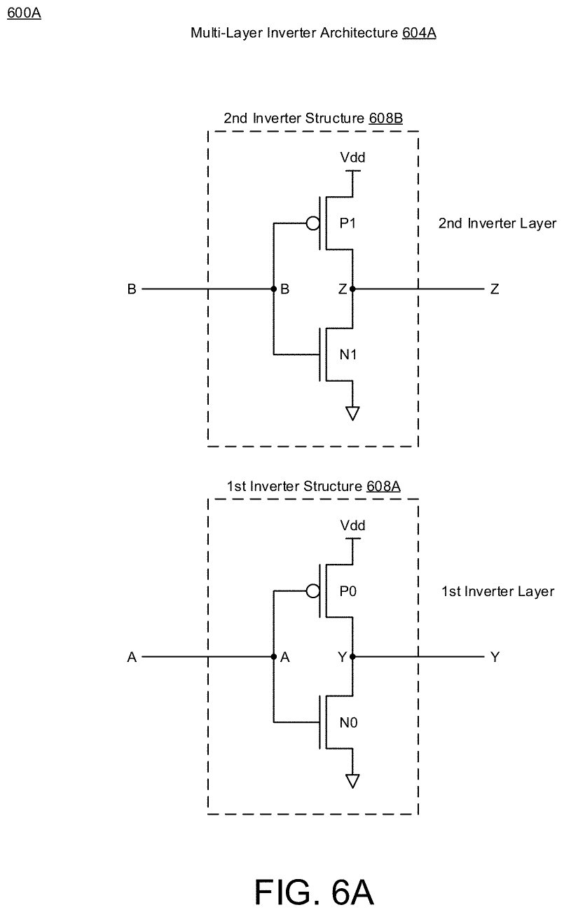

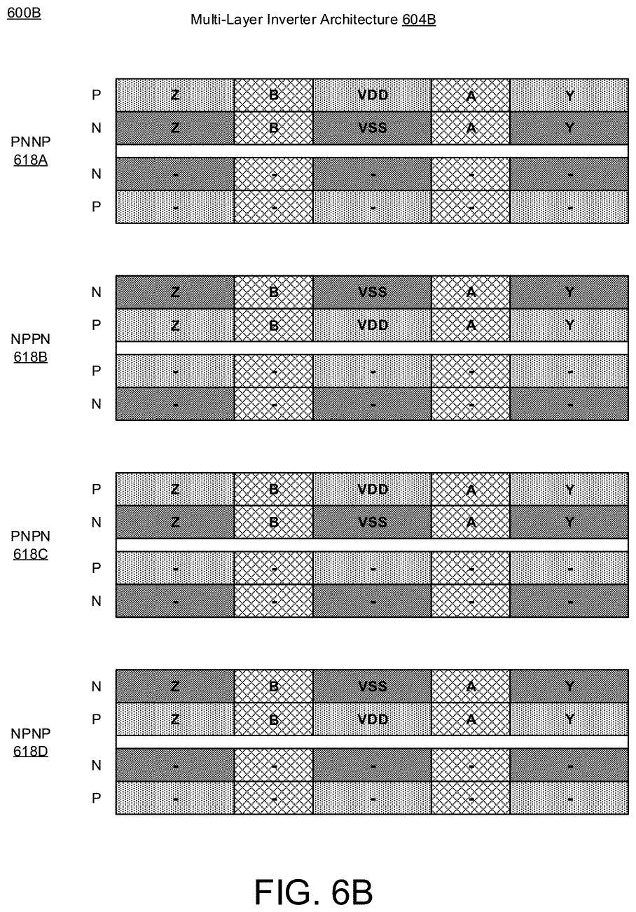

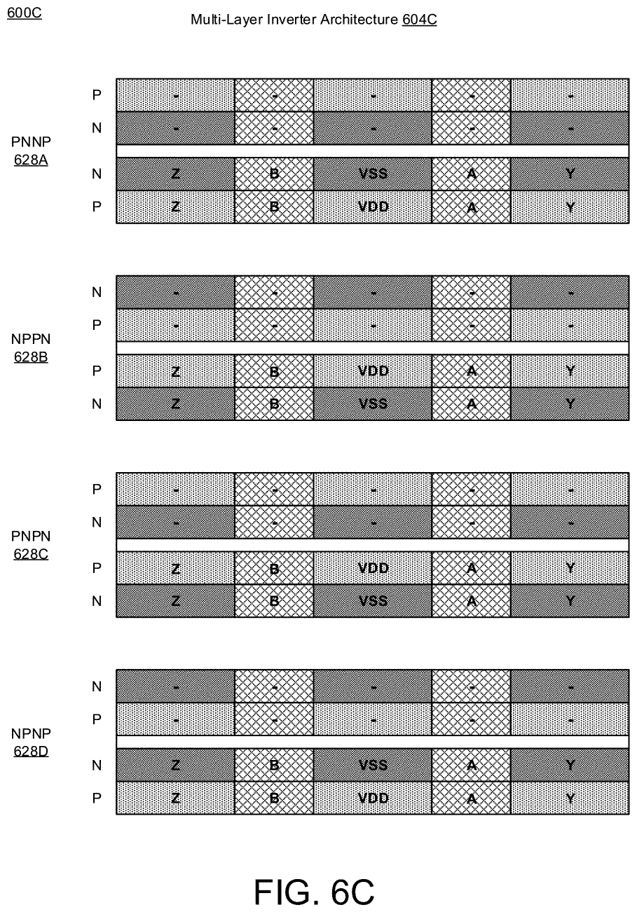

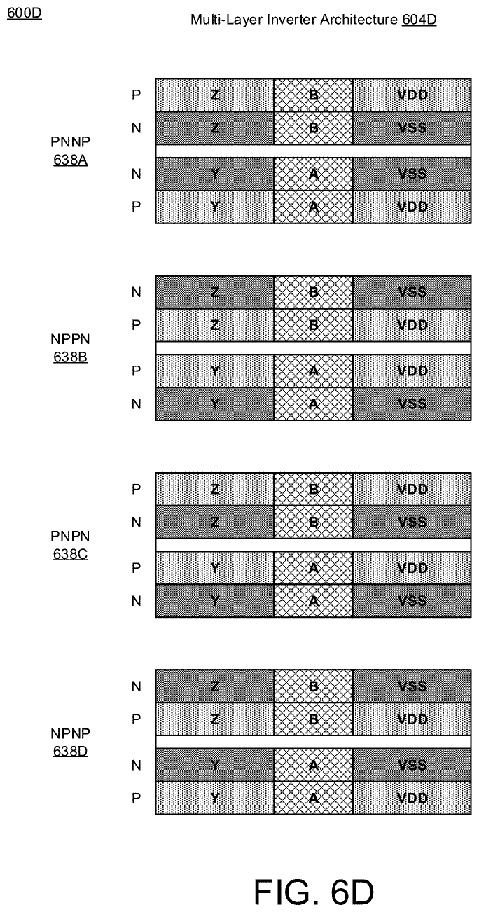

FIGS. 6A-6D illustrate schematic diagrams of multi-layer inverter architecture in accordance with implementations described herein. In some scenarios, the multi-layer inverter architecture may refer to a dual stacked inverter structure. Also, FIG. 6A shows a schematic diagram 600A of multi-layer inverter architecture 604A, FIG. 6B shows a layout diagram 600B of multi-layer inverter architecture 604B, FIG. 6C shows another layout diagram 600C of multi-layer inverter architecture 604C, and in addition, FIG. 6D shows another layout diagram 600D of multi-layer inverter architecture 604D.

In some implementations, multi-layer inverter architecture may be implemented as a system or device having various integrated circuit (IC) components that are arranged and coupled together as an assemblage or combination of parts that provide for physical layout designs and various related structures. In some instances, a method of designing, providing and building multi-layer inverter architecture as an integrated system or device may involve use of the various IC circuit components described herein so as to implement fabrication schemes and techniques associated therewith. Also, the inverter architecture may be integrated with computing circuitry and related components on a single chip, and the multi-layer inverter architecture may be implemented in various embedded systems for automotive, electronic, mobile, server and Internet-of-things (IoT) applications.

As shown in FIG. 6A, the multi-layer inverter architecture 604A may include a multi-layered device with multiple inverter structures 608A, 608B, including, e.g., a first inverter layer and a second inverter layer. In various scenarios, the inverter structures 608A, 608B may be configured with a multi-transistor inverter structure for various logic based applications, including, e.g., multi-transistor logic based applications. In various scenarios, memory stores a data value while logic performs some operation.

In some implementations, the two-transistors (2T) of each 2T inverter structure 608A, 608B may have at least one N-type metal-oxide-semiconductor (NMOS) transistor (N0, N1) along with at least one P-type MOS (PMOS) transistor (P0, P1), wherein the first inverter structure 608A has transistors (N0, P0) formed in the first inverter layer, and also, the second inverter structure 608B has transistors (N1, P1) formed in the second inverter layer. In some scenarios, the first inverter structure 608A may have an input at node (A) and an output at node (Y), wherein the transistors (N0, P0) are coupled in series between the supply voltage (VDD) and ground (VSS), and wherein the input at node (A) is coupled to the gates of transistors (N0, P0), and wherein the output is coupled to node (Y), which is disposed between transistors (N0, P0). Also, the second inverter structure 608B may have an input at node (B) and an output at node (Z), wherein the transistors (N1, P1) are coupled in series between the supply voltage (VDD) and ground (VSS), and wherein the input at node (B) is coupled to the gates of transistors (N1, P1), and wherein the output is coupled to node (Z), which is disposed between transistors (N1, P1).

As shown in the cross-section in FIG. 6B, the multi-layer inverter architecture 604B may refer to a multi-layer device having a multi-stack device structure for use in various logic based circuit architecture, such as, e.g., multi-layered inverters. The multi-stack device structure may have P-type transistors and N-type transistors that are arranged vertically in a multi-transistor stack configuration. The multi-layer device may have the first inverter layer and the second inverter layer, wherein the first inverter layer may include a first 2-device stack with first transistors, and wherein the second inverter layer may include a second 2-device stack with second transistors. Also, when multiple layers are combined, the second layer is disposed on the first layer so as to form multi-device stack structure. In various scenarios, memory is configured to store a data value while logic is configured to perform some operation.

In some scenarios, the multi-layer inverter architecture 604B may have a multi-layered P-over-N-over-N-over-P (PNNP) multi-transistor stack configuration 618A. In this instance, as shown in FIG. 6B, the first inverter layer (or bottom layer) may have a first 2-stack device arranged in the N-over-P (NP) multi-transistor stack configuration, and the second inverter layer (or top layer) may have a second 2-stack device arranged in the P-over-N (PN) multi-transistor stack configuration. Moreover, in some instances, when the multiple layers are combined, the top PN layer is disposed on the bottom (bot) NP layer so as to form the PNNP multi-transistor stack configuration 618A.

In some implementations, from left-to-right, the first inverter layer has a bottom (bot) P-layer with uncoupled (−) P-regions and uncoupled (−) gate regions, and further, from left-to-right, the first inverter layer has a bottom (bot) N-layer with uncoupled (−) N-regions and uncoupled (−) gate regions.

In some scenarios, from left-to-right, the second inverter layer includes a top N-layer with an N-region coupled to node (Z) of second inverter structure 608B, a gate region coupled to node (B) of second inverter structure 608B, another N-region coupled to ground (VSS), another gate region coupled to node (A) of first inverter structure 608A, and another N-region coupled to node (Y) of first inverter structure 608A. Moreover, from left-to-right, the second inverter layer includes a top P-layer with a P-region coupled to node (Z) of second inverter structure 608B, a gate region coupled to node (B) of second inverter structure 608B, another P-region coupled to supply voltage (VDD), another gate region coupled to node (A) of first inverter structure 608A, and another P-region coupled to node (Y) of first inverter structure 608A.

In some scenarios, the multi-layer inverter architecture 604B may have a multi-layered N-over-P-over-P-over-N(NPPN) multi-transistor stack configuration 618B. In this instance, as shown in FIG. 6B, the first inverter layer (or bottom layer) may have a first 2-stack device arranged in the P-over-N (PN) multi-transistor stack configuration, and the second inverter layer (or top layer) may have a second 2-stack device arranged in the N-over-P (NP) multi-transistor stack configuration. Moreover, in some instances, when the multiple layers are combined, the top NP layer is disposed on the bottom (bot) PN layer so as to form the NPPN multi-transistor stack configuration 618B.

In some implementations, from left-to-right, the first inverter layer has a bottom (bot) N-layer with uncoupled (−) N-regions and uncoupled (−) gate regions, and further, from left-to-right, the first inverter layer has a bottom (bot) P-layer with uncoupled (−) P-regions and uncoupled (−) gate regions.

In some scenarios, from left-to-right, the second inverter layer has a top P-layer with a P-region coupled to node (Z) of second inverter structure 608B, a gate region coupled to node (B) of second inverter structure 608B, another P-region coupled to supply voltage (VDD), another gate region coupled to node (A) of first inverter structure 608A, and another P-region coupled to node (Y) of first inverter structure 608A. Moreover, from left-to-right, the second inverter layer has a top N-layer with an N-region coupled to node (Z) of second inverter structure 608B, a gate region coupled to node (B) of second inverter structure 608B, another N-region coupled to ground (VSS), another gate region coupled to node (A) of first inverter structure 608A, and another N-region coupled to node (Y) of first inverter structure 608A.

In some scenarios, the multi-layer inverter architecture 604B may have a multi-layered P-over-N-over-P-over-N (PNPN) multi-transistor stack configuration 618C. In this instance, as shown in FIG. 6B, the first inverter layer (or bottom layer) may have a first 2-stack device arranged in the P-over-N (PN) multi-transistor stack configuration, and the second inverter layer (or top layer) may have a second 2-stack device arranged in the P-over-N (PN) multi-transistor stack configuration. Moreover, in some instances, when the multiple layers are combined, the top PN layer is disposed on the bottom (bot) PN layer so as to form the PNPN multi-transistor stack configuration 618C.

In some implementations, from left-to-right, the first inverter layer has a bottom (bot) N-layer with uncoupled (−) N-regions and uncoupled (−) gate regions, and further, from left-to-right, the first inverter layer has a bottom (bot) P-layer with uncoupled (−) P-regions and uncoupled (−) gate regions.

In some scenarios, from left-to-right, the second inverter layer includes a top N-layer with an N-region coupled to node (Z) of second inverter structure 608B, a gate region coupled to node (B) of second inverter structure 608B, another N-region coupled to ground (VSS), another gate region coupled to node (A) of first inverter structure 608A, and another N-region coupled to node (Y) of first inverter structure 608A. Moreover, from left-to-right, the second inverter layer includes a top P-layer with a P-region coupled to node (Z) of second inverter structure 608B, a gate region coupled to node (B) of second inverter structure 608B, another P-region coupled to supply voltage (VDD), another gate region coupled to node (A) of first inverter structure 608A, and another P-region coupled to node (Y) of first inverter structure 608A.

In some scenarios, the multi-layer inverter architecture 604B may have a multi-layered N-over-P-over-N-over-P (NPNP) multi-transistor stack configuration 618D. In this instance, as shown in FIG. 6B, the first inverter layer (or bottom layer) may have a first 2-stack device arranged in the N-over-P (NP) multi-transistor stack configuration, and the second inverter layer (or top layer) may have a second 2-stack device arranged in the N-over-P (NP) multi-transistor stack configuration. Moreover, in some instances, when the multiple layers are combined, the top NP layer is disposed on the bottom (bot) NP layer so as to form the NPNP multi-transistor stack configuration 618D.

In some implementations, from left-to-right, the first inverter layer has a bottom (bot) P-layer with uncoupled (−) P-regions and uncoupled (−) gate regions, and further, from left-to-right, the first inverter layer has a bottom (bot) N-layer with uncoupled (−) N-regions and uncoupled (−) gate regions.

In some scenarios, from left-to-right, the second inverter layer has a top P-layer with a P-region coupled to node (Z) of second inverter structure 608B, a gate region coupled to node (B) of second inverter structure 608B, another P-region coupled to supply voltage (VDD), another gate region coupled to node (A) of first inverter structure 608A, and another P-region coupled to node (Y) of first inverter structure 608A. Moreover, from left-to-right, the second inverter layer has a top N-layer with an N-region coupled to node (Z) of second inverter structure 608B, a gate region coupled to node (B) of second inverter structure 608B, another N-region coupled to ground (VSS), another gate region coupled to node (A) of first inverter structure 608A, and another N-region coupled to node (Y) of first inverter structure 608A.

As shown in FIG. 6C, the multi-layer inverter architecture 604C may refer to a multi-layer device having a multi-stack device structure for use in various logic based circuit architecture, such as, e.g., multi-layered inverters. The multi-stack device structure may have P-type transistors and N-type transistors that are arranged vertically in a multi-transistor stack configuration. The multi-layer device may have the first inverter layer and the second inverter layer, wherein the first inverter layer may include a first 2-device stack with first transistors, and wherein the second inverter layer may include a second 2-device stack with second transistors. Also, when multiple layers are combined, the second layer is disposed on the first layer so as to form multi-device stack structure.

In various scenarios, the multi-layer inverter architecture 604C shown in FIG. 6C refers to a swapped or inverted configuration when compared to the multi-layer inverter architecture 604B shown in FIG. 6B. For instance, in reference to FIG. 6C, the PNNP multi-transistor stack configuration 628A is a swapped, flipped or inverted configuration of the multi-transistor stack configuration 618A in FIG. 6B. Also, in reference to FIG. 6C, the NPPN multi-transistor stack configuration 628B is a swapped, flipped or inverted configuration of the multi-transistor stack configuration 618B in FIG. 6B. In addition, in reference to FIG. 6C, the PNPN multi-transistor stack configuration 628C is a swapped, flipped or inverted configuration of the multi-transistor stack configuration 618C in FIG. 6B. Further, in reference to FIG. 6C, the NPNP multi-transistor stack configuration 628D is a swapped, flipped or inverted configuration of the multi-transistor stack configuration 618D in FIG. 6B.

As shown in FIG. 6D, the multi-layer inverter architecture 604D may refer to a multi-layer device having a multi-stack device structure for use in various logic based circuit architecture, such as, e.g., multi-layered inverters. The multi-stack device structure may have P-type transistors and N-type transistors that are arranged vertically in a multi-transistor stack configuration. The multi-layer device may have the first inverter layer and the second inverter layer, wherein the first inverter layer may include a first 2-device stack with first transistors, and wherein the second inverter layer may include a second 2-device stack with second transistors. Also, when multiple layers are combined, the second layer is disposed on the first layer so as to form multi-device stack structure.

In some scenarios, the multi-layer inverter architecture 604D may have a multi-layered P-over-N-over-N-over-P (PNNP) multi-transistor stack configuration 638A. In this instance, as shown in FIG. 6D, the first inverter layer (or bottom layer) may have a first 2-stack device arranged in the N-over-P (NP) multi-transistor stack configuration, and the second inverter layer (or top layer) may have a second 2-stack device arranged in the P-over-N (PN) multi-transistor stack configuration. Moreover, in some instances, when the multiple layers are combined, the top PN layer is disposed on the bottom (bot) NP layer so as to form the PNNP multi-transistor stack configuration 638A.

In some implementations, from left-to-right, the first inverter layer includes a bot P-layer with a P-region coupled to node (Y) of first inverter structure 608A, a gate region coupled to node (A) of first inverter structure 608A, and an N-region coupled to supply voltage (VDD). Also, from left-to-right, the first inverter layer includes a bot N-layer with an N-region coupled to node (Y) of first inverter structure 608A, a gate region coupled to node (A) of first inverter structure 608A, and an N-region coupled to ground (VSS).

Moreover, in some implementations, from left-to-right, the second inverter layer includes a top N-layer with an N-region coupled to node (Z) of second inverter structure 608B, a gate region coupled to node (B) of second inverter structure 608B, and an N-region coupled to ground (VSS). Also, from left-to-right, the second inverter layer has a top P-layer with a P-region coupled to node (Z) of second inverter structure 608B, a gate region coupled to node (B) of second inverter structure 608B, and a P-region coupled to supply voltage (VDD).

In some scenarios, the multi-layer inverter architecture 604D may have a multi-layered N-over-P-over-P-over-N(NPPN) multi-transistor stack configuration 638B. In this instance, as shown in FIG. 6D, the first inverter layer (or bottom layer) may have a first 2-stack device arranged in the P-over-N (PN) multi-transistor stack configuration, and the second inverter layer (or top layer) may have a second 2-stack device arranged in the N-over-P (NP) multi-transistor stack configuration. Moreover, in some instances, when the multiple layers are combined, the top NP layer is disposed on the bottom (bot) PN layer so as to form the NPPN multi-transistor stack configuration 638B.

In some implementations, from left-to-right, the first inverter layer includes a bot N-layer having an N-region coupled to node (Y) of first inverter structure 608A, a gate region coupled to node (A) of first inverter structure 608A, and N-region coupled to ground (VSS). Further, from left-to-right, the first inverter layer has a bot P-layer with a P-region coupled to node (Y) of first inverter structure 608A, a gate region coupled to node (A) of first inverter structure 608A, and an N-region coupled to supply voltage (VDD).

Moreover, in some implementations, from left-to-right, the second inverter layer has a top P-layer with a P-region coupled to node (Z) of second inverter structure 608B, a gate region coupled to node (B) of second inverter structure 608B, and a P-region coupled to supply voltage (VDD). Further, from left-to-right, the second inverter layer has a top N-layer with an N-region coupled to node (Z) of second inverter structure 608B, a gate region coupled to node (B) of second inverter structure 608B, and an N-region coupled to ground (VSS).

In some scenarios, the multi-layer inverter architecture 604D may have a multi-layered N-over-P-over-N-over-P (NPNP) multi-transistor stack configuration 638C. In this instance, as shown in FIG. 6D, the first inverter layer (or bottom layer) may have a first 2-stack device arranged in the P-over-N (PN) multi-transistor stack configuration, and the second inverter layer (or top layer) may have a second 2-stack device arranged in the P-over-N (PN) multi-transistor stack configuration. Moreover, in some instances, when the multiple layers are combined, the top PN layer is disposed on the bottom (bot) PN layer so as to form the PNPN multi-transistor stack configuration 638C.

In some implementations, from left-to-right, the first inverter layer includes a bot N-layer having an N-region coupled to node (Y) of first inverter structure 608A, a gate region coupled to node (A) of first inverter structure 608A, and an N-region coupled to ground (VSS). Further, from left-to-right, the first inverter layer has a bot P-layer with a P-region coupled to node (Y) of first inverter structure 608A, a gate region coupled to node (A) of first inverter structure 608A, and a P-region coupled to supply voltage (VDD).

Moreover, in some implementations, from left-to-right, the second inverter layer includes a top N-layer with an N-region coupled to node (Z) of second inverter structure 608B, a gate region coupled to node (B) of second inverter structure 608B, and an N-region coupled to ground (VSS). Also, from left-to-right, the second inverter layer has a top P-layer with a P-region coupled to node (Z) of second inverter structure 608B, a gate region coupled to node (B) of second inverter structure 608B, and a P-region coupled to supply voltage (VDD).

In some scenarios, the multi-layer inverter architecture 604D may have a multi-layered N-over-P-over-N-over-P (NPNP) multi-transistor stack configuration 638D. In this instance, as shown in FIG. 6D, the first inverter layer (or bottom layer) may have a first 2-stack device arranged in the N-over-P (NP) multi-transistor stack configuration, and the second inverter layer (or top layer) may have a second 2-stack device arranged in the N-over-P (NP) multi-transistor stack configuration. Moreover, in some instances, when the multiple layers are combined, the top NP layer is disposed on the bottom (bot) NP layer so as to form the NPNP multi-transistor stack configuration 638D.

In some implementations, from left-to-right, the first inverter layer includes a bot P-layer with a P-region coupled to node (Y) of first inverter structure 608A, a gate region coupled to node (A) of first inverter structure 608A, and an N-region coupled to supply voltage (VDD). Also, from left-to-right, the first inverter layer includes a bot N-layer with an N-region coupled to node (Y) of first inverter structure 608A, a gate region coupled to node (A) of first inverter structure 608A, and an N-region coupled to ground (VSS).

Moreover, in some implementations, from left-to-right, the second inverter layer has a top P-layer with a P-region coupled to node (Z) of second inverter structure 608B, a gate region coupled to node (B) of second inverter structure 608B, and a P-region coupled to supply voltage (VDD). Further, from left-to-right, the second inverter layer has a top N-layer with an N-region coupled to node (Z) of second inverter structure 608B, a gate region coupled to node (B) of second inverter structure 608B, and an N-region coupled to ground (VSS).

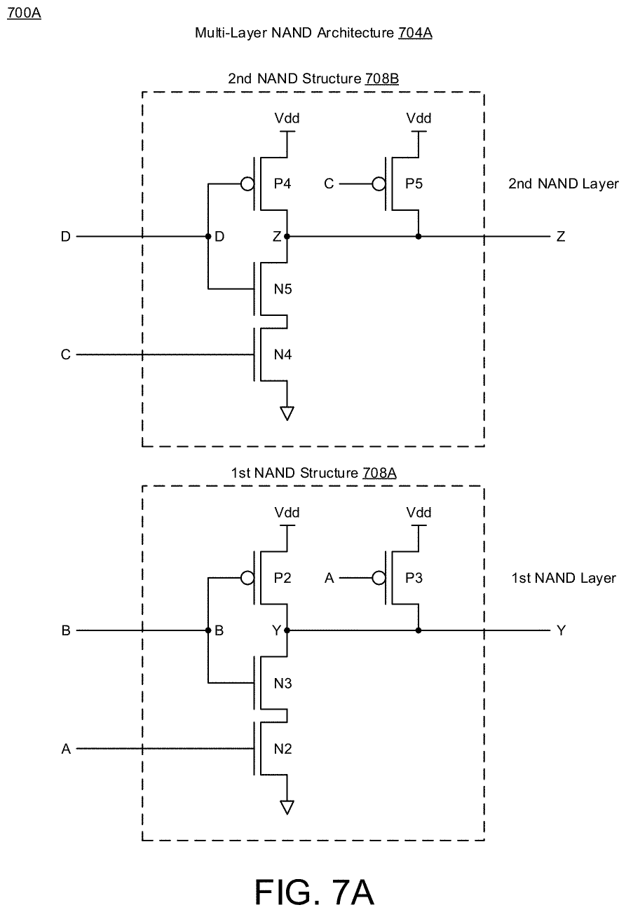

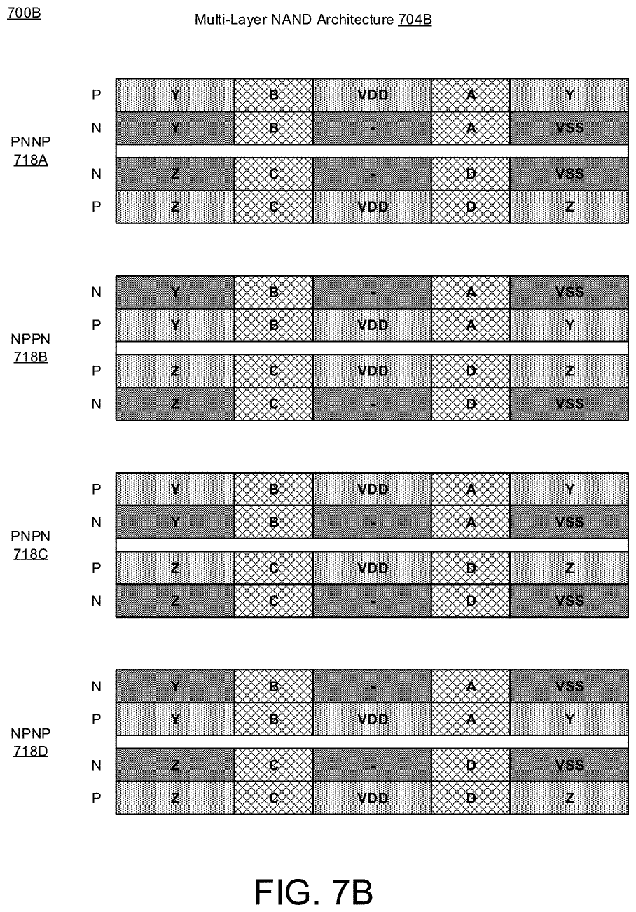

FIGS. 7A-7B illustrate schematic and physical layout diagrams of multi-layer NAND architecture in accordance with implementations described herein. In some scenarios, the multi-layer NAND architecture may refer to a dual stacked NAND structure. FIG. 7A shows a schematic diagram 700A of multi-layer NAND architecture 704A, and also, FIG. 7B shows a layout diagram 700B of multi-layer NAND architecture 704B.

In some implementations, multi-layer NAND architecture may be implemented as a system or device having various integrated circuit (IC) components that are arranged and coupled together as an assemblage or combination of parts that provide for physical layout designs and various related structures. In some instances, a method of designing, providing and building multi-layer NAND architecture as an integrated system or device may involve use of the various IC circuit components described herein so as to implement fabrication schemes and techniques associated therewith. Also, the NAND architecture may be integrated with computing circuitry and related components on a single chip, and the multi-layer NAND architecture may be implemented in various embedded systems for automotive, electronic, mobile, server and Internet-of-things (IoT) applications.

As shown in FIG. 7A, the multi-layer NAND architecture 704A may include a multi-layered device with multiple NAND structures 708A, 708B, including, e.g., a first NAND layer and a second NAND layer. In various scenarios, the NAND structures 708A, 708B may be configured with a multi-transistor NAND structure for various logic based applications, including, e.g., multi-transistor logic based applications.

In some implementations, the four-transistors (4T) of each 4T NAND structure 708A, 708B may have N-type metal-oxide-semiconductor (NMOS) transistors (N2, N3, N4, N5) along with P-type MOS (PMOS) transistors (P2, P3, P4, P5), wherein the first NAND structure 708A has transistors (N2, N3, P2, P3) formed in the first NAND layer, and the second NAND structure 708B has transistors (N4, N5, P4, P5) formed in the second NAND layer. In some scenarios, the first NAND structure 708A may have inputs at nodes (A, B) with an output at node (Y), wherein transistors (N2, N3, P2) are coupled in series between supply voltage (VDD) and ground (VSS), and transistor (P3) is coupled in parallel with transistor (P2). The input at node (A) is coupled to the gates of transistors (N2, P3), the input at node (B) is coupled to the gates of transistors (N3, P2), and the output is coupled to node (Y), which is disposed between transistors (N3, P2/P3). Also, the second NAND structure 708B may have inputs at nodes (C, D) with an output at node (Z), wherein transistors (N4, N5, P4) are coupled in series between supply voltage (VDD) and ground (VSS), and transistor (P5) is coupled in parallel with transistor (P4). The input at node (C) is coupled to the gates of transistors (N4, P5), the input at node (D) is coupled to the gates of transistors (N5, P4), and the output is coupled to node (Z), which is disposed between transistors (N5, P4/P3).

As shown in FIG. 7B, the multi-layer NAND architecture 704B may refer to a multi-layer device having a multi-stack device structure for use in various logic based circuit architecture, such as, e.g., multi-layered NANDs. The multi-stack device structure may have P-type transistors and N-type transistors that are arranged vertically in a multi-transistor stack configuration. The multi-layer device may have the first NAND layer and the second NAND layer, wherein the first NAND layer may include a first 2-device stack with first transistors, and wherein the second NAND layer may include a second 2-device stack with second transistors. Also, when multiple layers are combined, the second layer is disposed on the first layer so as to form multi-device stack structure.

In some scenarios, the multi-layer NAND architecture 704B may have a multi-layered P-over-N-over-N-over-P (PNNP) multi-transistor stack configuration 718A. In this instance, as shown in FIG. 7B, the first NAND layer (or bottom layer) may have a first 2-stack device arranged in the N-over-P (NP) multi-transistor stack configuration, and the second NAND layer (or top layer) may have a second 2-stack device arranged in the P-over-N (PN) multi-transistor stack configuration. Moreover, in some instances, when the multiple layers are combined, the top PN layer is disposed on the bottom (bot) NP layer so as to form the PNNP multi-transistor stack configuration 718A.

In some implementations, from left-to-right, the first NAND layer includes a bot P-layer with a P-region coupled to node (Z) of second NAND structure 708B, a gate region coupled to node (C) of second NAND structure 708B, a P-region coupled to supply voltage (VDD), a gate region coupled to node (D) of second NAND structure 708B, and a P-region coupled to node (Z) of second NAND structure 708B. Also, from left-to-right, the first NAND layer includes a bot N-layer with an N-region coupled to node (Z) of second NAND structure 708B, a gate region coupled to node (C) of second NAND structure 708B, an uncoupled (−) N-region, a gate region coupled to node (D) of second NAND structure 708B, and an N-region coupled to ground (VSS).

In some scenarios, from left-to-right, the second NAND layer includes a top N-layer with an N-region coupled to node (Y) of first NAND structure 708A, a gate region coupled to node (B) of first NAND structure 708A, an uncoupled (−) N-region, a gate region coupled to node (A) of first NAND structure 708A, and an N-region coupled to ground (VSS). Also, from left-to-right, the second NAND layer includes a top P-layer with a P-region coupled to node (Y) of first NAND structure 708A, a gate region coupled to node (B) of first NAND structure 708A, a P-region coupled to supply voltage (VDD), a gate region coupled to node (A) of first NAND structure 708A, and a P-region coupled to node (Y) of first NAND structure 708A.

In some scenarios, the multi-layer NAND architecture 704B may have a multi-layered N-over-P-over-P-over-N(NPPN) multi-transistor stack configuration 718B. In this instance, as shown in FIG. 7B, the first NAND layer (or bottom layer) may have a first 2-stack device arranged in the P-over-N (PN) multi-transistor stack configuration, and the second NAND layer (or top layer) may have a second 2-stack device arranged in the N-over-P (NP) multi-transistor stack configuration. Moreover, in some instances, when the multiple layers are combined, the top NP layer is disposed on the bottom (bot) PN layer so as to form the NPPN multi-transistor stack configuration 718B.

In some implementations, from left-to-right, the first NAND layer includes a bot N-layer with an N-region coupled to node (Z) of second NAND structure 708B, a gate region coupled to node (C) of second NAND structure 708B, an uncoupled (−) N-region, a gate region coupled to node (D) of second NAND structure 708B, and an N-region coupled to ground (VSS). Also, from left-to-right, the first NAND layer includes a bot P-layer with a P-region coupled to node (Z) of second NAND structure 708B, a gate region coupled to node (C) of second NAND structure 708B, a P-region coupled to supply voltage (VDD), a gate region coupled to node (D) of second NAND structure 708B, and a P-region coupled to node (Z) of second NAND structure 708B.

In some scenarios, from left-to-right, the second NAND layer includes a top P-layer with a P-region coupled to node (Y) of first NAND structure 708A, a gate region coupled to node (B) of first NAND structure 708A, a P-region coupled to supply voltage (VDD), a gate region coupled to node (A) of first NAND structure 708A, and a P-region coupled to node (Y) of first NAND structure 708A. Further, from left-to-right, the second NAND layer includes a top N-layer with an N-region coupled to node (Y) of first NAND structure 708A, a gate region coupled to node (B) of first NAND structure 708A, an uncoupled (−) N-region, a gate region coupled to node (A) of first NAND structure 708A, and an N-region coupled to ground (VSS).

In some scenarios, the multi-layer NAND architecture 704B may have a multi-layered P-over-N-over-P-over-N (PNPN) multi-transistor stack configuration 718C. In this instance, as shown in FIG. 7B, the first NAND layer (or bottom layer) may have a first 2-stack device arranged in the P-over-N (PN) multi-transistor stack configuration, and the second NAND layer (or top layer) may have a second 2-stack device arranged in the P-over-N (PN) multi-transistor stack configuration. Moreover, in some instances, when the multiple layers are combined, the top PN layer is disposed on the bottom (bot) PN layer so as to form the PNPN multi-transistor stack configuration 718C.

In some implementations, from left-to-right, the first NAND layer includes a bot N-layer with an N-region coupled to node (Z) of second NAND structure 708B, a gate region coupled to node (C) of second NAND structure 708B, an uncoupled (−) N-region, a gate region coupled to node (D) of second NAND structure 708B, and an N-region coupled to ground (VSS). Also, from left-to-right, the first NAND layer includes a bot P-layer with a P-region coupled to node (Z) of second NAND structure 708B, a gate region coupled to node (C) of second NAND structure 708B, a P-region coupled to supply voltage (VDD), a gate region coupled to node (D) of second NAND structure 708B, and a P-region coupled to node (Z) of second NAND structure 708B.

In some scenarios, from left-to-right, the second NAND layer includes a top N-layer with an N-region coupled to node (Y) of first NAND structure 708A, a gate region coupled to node (B) of first NAND structure 708A, an uncoupled (−) N-region, a gate region coupled to node (A) of first NAND structure 708A, and an N-region coupled to ground (VSS). Also, from left-to-right, the second NAND layer includes a top P-layer with a P-region coupled to node (Y) of first NAND structure 708A, a gate region coupled to node (B) of first NAND structure 708A, a P-region coupled to supply voltage (VDD), a gate region coupled to node (A) of first NAND structure 708A, and a P-region coupled to node (Y) of first NAND structure 708A.

In some scenarios, the multi-layer NAND architecture 704B may have a multi-layered N-over-P-over-N-over-P (NPNP) multi-transistor stack configuration 718D. In this instance, as shown in FIG. 7B, the first NAND layer (or bottom layer) may have a first 2-stack device arranged in the N-over-P (NP) multi-transistor stack configuration, and the second NAND layer (or top layer) may have a second 2-stack device arranged in the N-over-P (NP) multi-transistor stack configuration. Moreover, in some instances, when the multiple layers are combined, the top NP layer is disposed on the bottom (bot) NP layer so as to form the NPNP multi-transistor stack configuration 718D.

In some implementations, from left-to-right, the first NAND layer includes a bot P-layer with a P-region coupled to node (Z) of second NAND structure 708B, a gate region coupled to node (C) of second NAND structure 708B, a P-region coupled to supply voltage (VDD), a gate region coupled to node (D) of second NAND structure 708B, and a P-region coupled to node (Z) of second NAND structure 708B. Also, from left-to-right, the first NAND layer includes a bot N-layer with an N-region coupled to node (Z) of second NAND structure 708B, a gate region coupled to node (C) of second NAND structure 708B, an uncoupled (−) N-region, a gate region coupled to node (D) of second NAND structure 708B, and an N-region coupled to ground (VSS).

In some scenarios, from left-to-right, the second NAND layer includes a top P-layer with a P-region coupled to node (Y) of first NAND structure 708A, a gate region coupled to node (B) of first NAND structure 708A, a P-region coupled to supply voltage (VDD), a gate region coupled to node (A) of first NAND structure 708A, and a P-region coupled to node (Y) of first NAND structure 708A. Further, from left-to-right, the second NAND layer includes a top N-layer with an N-region coupled to node (Y) of first NAND structure 708A, a gate region coupled to node (B) of first NAND structure 708A, an uncoupled (−) N-region, a gate region coupled to node (A) of first NAND structure 708A, and an N-region coupled to ground (VSS).

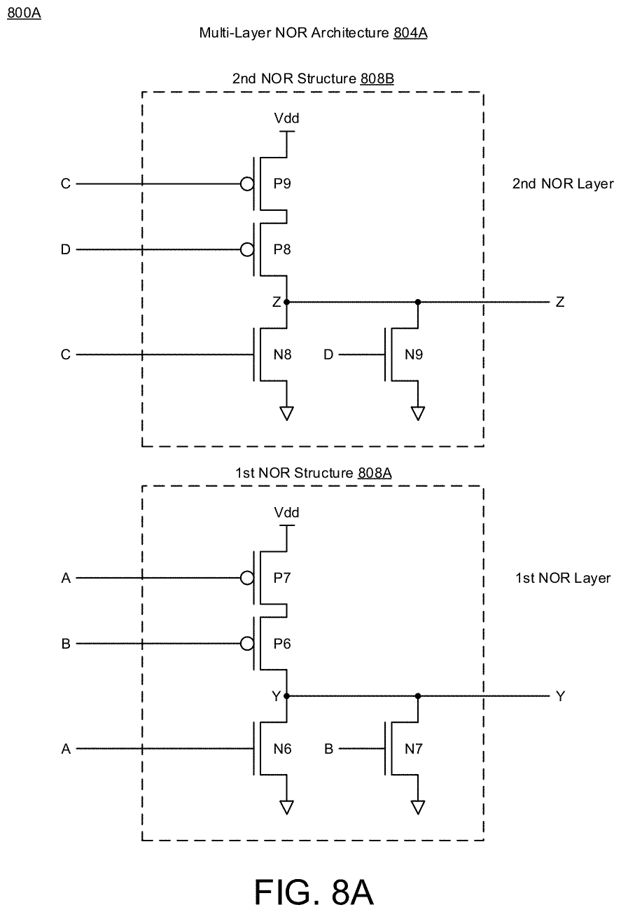

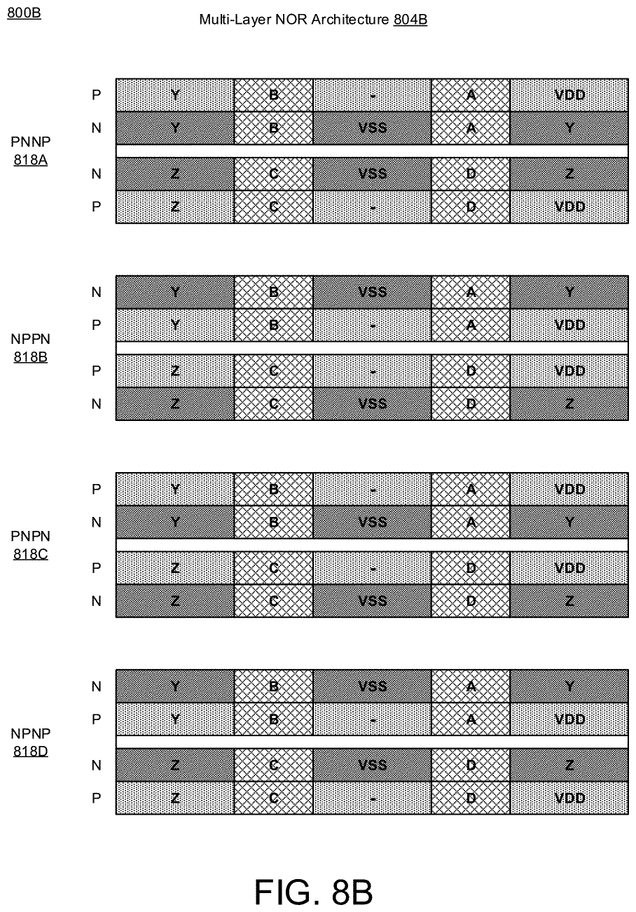

FIGS. 8A-8B illustrate schematic diagrams and physical layout of multi-layer NOR architecture in accordance with implementations described herein. In some scenarios, the multi-layer NOR architecture may refer to a dual stacked NOR structure. FIG. 8A shows a schematic diagram 800A of multi-layer NOR architecture 804A, and also, FIG. 8B shows a layout diagram 800B of multi-layer NOR architecture 804B.

In some implementations, multi-layer NOR architecture may be implemented as a system or device having various integrated circuit (IC) components that are arranged and coupled together as an assemblage or combination of parts that provide for physical layout designs and various related structures. In some instances, a method of designing, providing and building multi-layer NOR architecture as an integrated system or device may involve use of the various IC circuit components described herein so as to implement fabrication schemes and techniques associated therewith. Also, the NOR architecture may be integrated with computing circuitry and related components on a single chip, and the multi-layer NOR architecture may be implemented in various embedded systems for automotive, electronic, mobile, server and Internet-of-things (IoT) applications.

As shown in FIG. 8A, the multi-layer NOR architecture 804A may include a multi-layered device with multiple NOR structures 808A, 808B, including, e.g., a first NOR layer and a second NOR layer. In some scenarios, the NOR structures 808A, 808B may be configured with a multi-transistor NOR structure for various logic based applications, including, e.g., multi-transistor logic based applications.

In some implementations, the four-transistors (4T) of each 4T NOR structure 808A, 808B may have N-type metal-oxide-semiconductor (NMOS) transistors (N6, N7, N8, N9) along with P-type MOS (PMOS) transistors (P6, P7, P8, P9), wherein the first NOR structure 808A has transistors (N6, N7, P6, P7) formed in the first NOR layer, and the second NOR structure 808B has transistors (N8, N9, P8, P9) formed in the second NOR layer. In some scenarios, the first NOR structure 808A may have inputs at nodes (A, B) with an output at node (Y), wherein transistors (N6, P6, P7) are coupled in series between supply voltage (VDD) and ground (VSS), and transistor (N7) is coupled in parallel with transistor (N6). The input at node (A) is coupled to the gates of transistors (N6, P7), the input at node (B) is coupled to the gates of transistors (N7, P6), and the output is coupled to node (Y), which is disposed between transistors (N6/N7, P6). Further, the second NOR structure 808B has inputs at nodes (C, D) with an output at node (Z), wherein transistors (N8, P8, P9) are coupled in series between supply voltage (VDD) and ground (VSS), and transistor (N9) is coupled in parallel with transistor (N8). In addition, the input at node (C) is coupled to the gates of transistors (N8, P9), the input at node (D) is coupled to the gates of transistors (N9, P8), and the output is coupled to node (Z), which is disposed between transistors (N8/N9, P8).

As shown in FIG. 8B, the multi-layer NOR architecture 804B may refer to a multi-layer device having a multi-stack device structure for use in various logic based circuit architecture, such as, e.g., multi-layered NORs. The multi-stack device structure may have P-type transistors and N-type transistors that are arranged vertically in a multi-transistor stack configuration. The multi-layer device may have the first NOR layer and the second NOR layer, wherein the first NOR layer may include a first 2-device stack with first transistors, and wherein the second NOR layer may include a second 2-device stack with second transistors. Further, when multiple layers are combined, the second layer is disposed on the first layer so as to form multi-device stack structure.

In some scenarios, the multi-layer NOR architecture 804B may have a multi-layered P-over-N-over-N-over-P (PNNP) multi-transistor stack configuration 818A. In this instance, as shown in FIG. 8B, the first NOR layer (or bottom layer) may have a first 2-stack device arranged in the N-over-P (NP) multi-transistor stack configuration, and the second NOR layer (or top layer) may have a second 2-stack device arranged in the P-over-N (PN) multi-transistor stack configuration. Moreover, in some instances, when the multiple layers are combined, the top PN layer is disposed on the bottom (bot) NP layer so as to form the PNNP multi-transistor stack configuration 818A.

In some implementations, from left-to-right, the first NOR layer includes a bot P-layer with a P-region coupled to node (Z) of second NOR structure 808B, a gate region coupled to node (C) of second NOR structure 808B, an uncoupled (−) P-region, a gate region coupled to node (D) of second NOR structure 808B, and a P-region coupled to supply voltage (VDD). Also, from left-to-right, the first NOR layer includes a bot N-layer with an N-region coupled to node (Z) of second NOR structure 808B, a gate region coupled to node (C) of second NOR structure 808B, an N-region coupled to ground (VSS), a gate region coupled to node (D) of second NOR structure 808B, and an N-region coupled to node (Z) of the second NOR structure 808B.

In some scenarios, from left-to-right, the second NOR layer includes a top N-layer with an N-region coupled to node (Y) of first NOR structure 808A, a gate region coupled to node (B) of first NOR structure 808A, an N-region coupled to ground (VSS), a gate region coupled to node (A) of first NOR structure 808A, and an N-region coupled to node (Y) of first NOR structure 808A. Further, from left-to-right, the second NOR layer includes a top P-layer with a P-region coupled to node (Y) of first NOR structure 808A, a gate region coupled to node (B) of first NOR structure 808A, an uncoupled (−) P-region, a gate region coupled to node (A) of first NOR structure 808A, and a P-region coupled to supply voltage (VDD).

In some scenarios, the multi-layer NOR architecture 804B may have a multi-layered N-over-P-over-P-over-N(NPPN) multi-transistor stack configuration 818B. In this instance, as shown in FIG. 8B, the first NOR layer (or bottom layer) may have a first 2-stack device arranged in the P-over-N (PN) multi-transistor stack configuration, and the second NOR layer (or top layer) may have a second 2-stack device arranged in the N-over-P (NP) multi-transistor stack configuration. Moreover, in some instances, when the multiple layers are combined, the top NP layer is disposed on the bottom (bot) PN layer so as to form the NPPN multi-transistor stack configuration 818B.

In some implementations, from left-to-right, the first NOR layer includes a bot N-layer with an N-region coupled to node (Z) of second NOR structure 808B, a gate region coupled to node (C) of second NOR structure 808B, an N-region coupled to ground (VSS), a gate region coupled to node (D) of second NOR structure 808B, and an N-region coupled to node (Z) of the second NOR structure 808B. Also, from left-to-right, the first NOR layer includes a bot P-layer with a P-region coupled to node (Z) of second NOR structure 808B, a gate region coupled to node (C) of second NOR structure 808B, an uncoupled (−) P-region, a gate region coupled to node (D) of second NOR structure 808B, and a P-region coupled to supply voltage (VDD).

In some scenarios, from left-to-right, the second NOR layer includes a top P-layer with a P-region coupled to node (Y) of first NOR structure 808A, a gate region coupled to node (B) of first NOR structure 808A, an uncoupled (−) P-region, a gate region coupled to node (A) of first NOR structure 808A, and a P-region coupled to supply voltage (VDD). Also, from left-to-right, the second NOR layer includes a top N-layer with an N-region coupled to node (Y) of first NOR structure 808A, a gate region coupled to node (B) of first NOR structure 808A, an N-region coupled to ground (VSS), a gate region coupled to node (A) of first NOR structure 808A, and an N-region coupled to node (Y) of first NOR structure 808A.

In some scenarios, the multi-layer NOR architecture 804B may have a multi-layered P-over-N-over-P-over-N (PNPN) multi-transistor stack configuration 818C. In this instance, as shown in FIG. 8B, the first NOR layer (or bottom layer) may have a first 2-stack device arranged in the P-over-N (PN) multi-transistor stack configuration, and the second NOR layer (or top layer) may have a second 2-stack device arranged in the P-over-N (PN) multi-transistor stack configuration. Moreover, in some instances, when the multiple layers are combined, the top PN layer is disposed on the bottom (bot) PN layer so as to form the PNPN multi-transistor stack configuration 818C.

In some implementations, from left-to-right, the first NOR layer includes a bot N-layer with an N-region coupled to node (Z) of second NOR structure 808B, a gate region coupled to node (C) of second NOR structure 808B, an N-region coupled to ground (VSS), a gate region coupled to node (D) of second NOR structure 808B, and an N-region coupled to node (Z) of the second NOR structure 808B. Also, from left-to-right, the first NOR layer includes a bot P-layer with a P-region coupled to node (Z) of second NOR structure 808B, a gate region coupled to node (C) of second NOR structure 808B, an uncoupled (−) P-region, a gate region coupled to node (D) of second NOR structure 808B, and a P-region coupled to supply voltage (VDD).

In some scenarios, from left-to-right, the second NOR layer includes a top N-layer with an N-region coupled to node (Y) of first NOR structure 808A, a gate region coupled to node (B) of first NOR structure 808A, an N-region coupled to ground (VSS), a gate region coupled to node (A) of first NOR structure 808A, and an N-region coupled to node (Y) of first NOR structure 808A. Further, from left-to-right, the second NOR layer includes a top P-layer with a P-region coupled to node (Y) of first NOR structure 808A, a gate region coupled to node (B) of first NOR structure 808A, an uncoupled (−) P-region, a gate region coupled to node (A) of first NOR structure 808A, and a P-region coupled to supply voltage (VDD).

In some scenarios, the multi-layer NOR architecture 804B may have a multi-layered N-over-P-over-N-over-P (NPNP) multi-transistor stack configuration 818D. In this instance, as shown in FIG. 8B, the first NOR layer (or bottom layer) may have a first 2-stack device arranged in the N-over-P (NP) multi-transistor stack configuration, and the second NOR layer (or top layer) may have a second 2-stack device arranged in the N-over-P (NP) multi-transistor stack configuration. Moreover, in some instances, when the multiple layers are combined, the top NP layer is disposed on the bottom (bot) NP layer so as to form the NPNP multi-transistor stack configuration 818D.

In some implementations, from left-to-right, the first NOR layer includes a bot P-layer with a P-region coupled to node (Z) of second NOR structure 808B, a gate region coupled to node (C) of second NOR structure 808B, an uncoupled (−) P-region, a gate region coupled to node (D) of second NOR structure 808B, and a P-region coupled to supply voltage (VDD). Also, from left-to-right, the first NOR layer includes a bot N-layer with an N-region coupled to node (Z) of second NOR structure 808B, a gate region coupled to node (C) of second NOR structure 808B, an N-region coupled to ground (VSS), a gate region coupled to node (D) of second NOR structure 808B, and an N-region coupled to node (Z) of the second NOR structure 808B.

In some scenarios, from left-to-right, the second NOR layer includes a top P-layer with a P-region coupled to node (Y) of first NOR structure 808A, a gate region coupled to node (B) of first NOR structure 808A, an uncoupled (−) P-region, a gate region coupled to node (A) of first NOR structure 808A, and a P-region coupled to supply voltage (VDD). Also, from left-to-right, the second NOR layer includes a top N-layer with an N-region coupled to node (Y) of first NOR structure 808A, a gate region coupled to node (B) of first NOR structure 808A, an N-region coupled to ground (VSS), a gate region coupled to node (A) of first NOR structure 808A, and an N-region coupled to node (Y) of first NOR structure 808A.

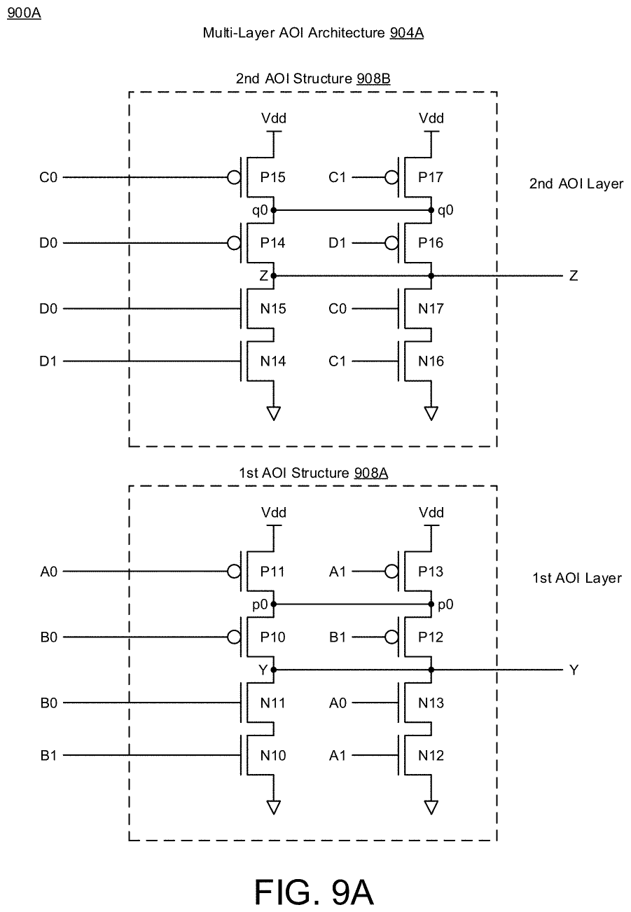

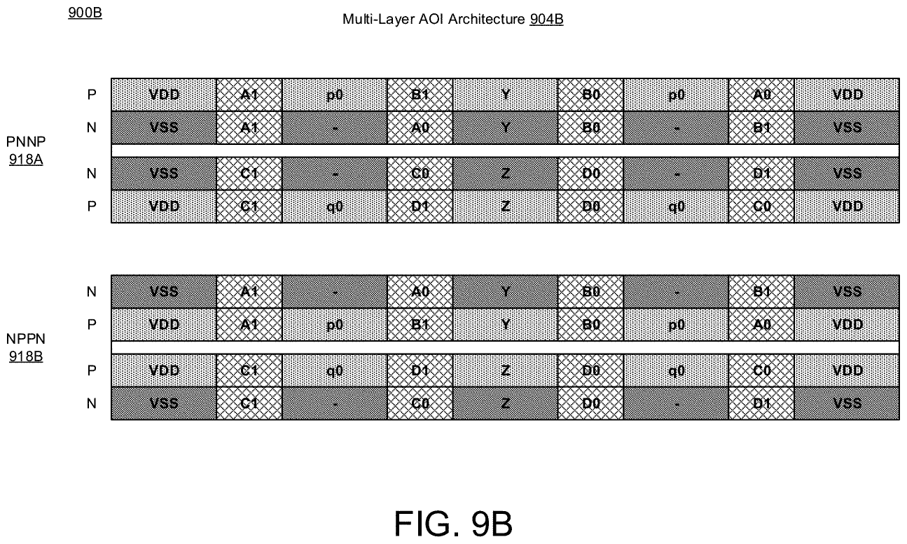

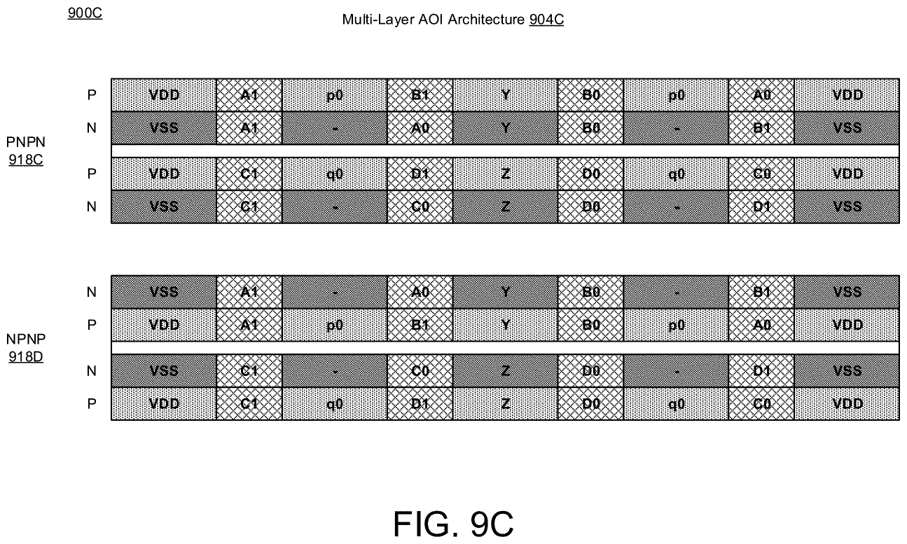

FIGS. 9A-9C illustrate schematic diagrams and physical layout* of multi-layer AND-OR-Invert (AOI) architecture in accordance with implementations described herein. In various scenarios, the multi-layer AOI architecture refers to a dual stacked AOI structure. FIG. 9A shows a schematic diagram 900A of multi-layer AOI architecture 904A, FIG. 9B shows a layout diagram 900B of multi-layer AOI architecture 904B and also, FIG. 9C shows another layout diagram 900C of multi-layer AOI architecture 904C.

In some implementations, multi-layer AOI architecture may be implemented as a system or device having various integrated circuit (IC) components that are arranged and coupled together as an assemblage or combination of parts that provide for physical layout designs and various related structures. In some instances, a method of designing, providing and building multi-layer AOI architecture as an integrated system or device may involve use of the various IC circuit components described herein so as to implement fabrication schemes and techniques associated therewith. Also, the AOI architecture may be integrated with computing circuitry and related components on a single chip, and the multi-layer AOI architecture may be implemented in various embedded systems for automotive, electronic, mobile, server and Internet-of-things (IoT) applications.

As shown in FIG. 9A, the multi-layer AOI architecture 904A may include a multi-layered device with multiple AOI structures 908A, 908B, including, e.g., a first AOI layer and a second AOI layer. In various scenarios, the AOI structures 908A, 908B may be configured with a multi-transistor AOI structure for various logic based applications, including, e.g., multi-transistor logic based applications.

In some implementations, the eight-transistors (8T) of each 8T AOI structure 908A, 908B may include NMOS transistors (N10, N11, N12, N13, N14, N15, N16, N17) along with PMOS transistors (P10, P11, P12, P13, P14, P15, P16, P17), wherein the first AOI structure 908A has transistors (N10, N11, N12, N13, P10, P11, P12, P13) formed in the first AOI layer, and the second AOI structure 908B has transistors (N14, N15, N16, N17, P14, P15, P16, P17) formed in the second AOI layer.

The first AOI structure 908A may have inputs at nodes (A0, A1, B0, B1) with an output at node (Y), wherein transistors (N10, N11, P10, P11) are coupled in series between supply voltage (VDD) and ground (VSS), and transistors (N12, N13, P12, P13) are coupled in parallel with transistors (N10, N11, P10, P11). The inputs at nodes (A0, A1) are coupled to the gates of transistors (N12, N13, P11, P13), the inputs at nodes (B0, B1) are coupled to the gates of transistors (N10, N11, P10, P12), and the output is coupled to node (Y), which is disposed between transistors (N11/P10, N13/P12). Also, internal node (p0) may be disposed between transistors (P10/P11, P12/P13).

Also, the second AOI structure 908B may have inputs at nodes (C0, C1, D0, D1) with an output at node (Z), wherein transistors (N14, N15, P14, P15) are coupled in series between supply voltage (VDD) and ground (VSS), and transistors (N16, N17, P16, P17) are coupled in parallel with transistors (N14, N15, P14, P15). The inputs at nodes (C0, C1) are coupled to the gates of transistors (N16, N17, P15, P17), the inputs at nodes (D0, D1) are coupled to the gates of transistors (N14, N15, P14, P16), and the output is coupled to node (Z), which is disposed between transistors (N15/P14, N17/P16). Also, internal node (q0) may be disposed between transistors (P14/P15, P16/P17).

As shown in FIG. 9B, the multi-layer AOI architecture 904B may refer to a multi-layer device having a multi-stack device structure for use in various logic based circuit architecture, such as, e.g., multi-layered AOIs. The multi-stack device structure may have P-type transistors and N-type transistors that are arranged vertically in a multi-transistor stack configuration. The multi-layer device may have the first AOI layer and the second AOI layer, wherein the first AOI layer may include a first 2-device stack with first transistors, and wherein the second AOI layer may include a second 2-device stack with second transistors. Also, when multiple layers are combined, the second layer is disposed on the first layer so as to form multi-device stack structure.

In some scenarios, the multi-layer AOI architecture 904B may have a multi-layered P-over-N-over-N-over-P (PNNP) multi-transistor stack configuration 918A. In this instance, as shown in FIG. 9B, the first AOI layer (or bottom layer) may have a first 2-stack device arranged in the N-over-P (NP) multi-transistor stack configuration, and the second AOI layer (or top layer) may have a second 2-stack device arranged in the P-over-N (PN) multi-transistor stack configuration. Further, in some instances, when the multiple layers are combined, the top PN layer is disposed on the bottom (bot) NP layer so as to form the PNNP multi-transistor stack configuration 918A.

In some implementations, from left-to-right, the first AOI layer includes a bot P-layer with a P-region coupled to supply voltage (VDD), a gate region coupled to node (C1) of second AOI structure 908B, a P-region coupled to node (q0) of second AOI structure 908B, a gate region coupled to node (D1) of second AOI structure 908B, a P-region coupled to node (Z) of second AOI structure 908B, a gate region coupled to node (D0) of second AOI structure 908B, another P-region coupled to node (q0) of second AOI structure 908B, a gate region coupled to node (C0) of second AOI structure 908B, and another P-region coupled to supply voltage (VDD). Further, from left-to-right, the first AOI layer includes a bot N-layer with an N-region coupled to ground (VSS), a gate region coupled to node (C1) of second AOI structure 908B, an uncoupled (−) N-region, a gate region coupled to node (C0) of second AOI structure 908B, an N-region coupled to node (Z) of second AOI structure 908B, a gate region coupled to node (D0) of second AOI structure 908B, an uncoupled (−) N-region, a gate region coupled to node (D1) of second AOI structure 908B, and another N-region coupled to ground (VSS).

In some scenarios, from left-to-right, the second AOI layer includes a top N-layer with an N-region coupled to ground (VSS), a gate region coupled to node (A1) of first AOI structure 908A, an uncoupled (−) N-region, a gate region coupled to node (A0) of first AOI structure 908A, an N-region coupled to node (Y) of first AOI structure 908A, a gate region coupled to node (B0) of first AOI structure 908A, an uncoupled (−) N-region, a gate region coupled to node (B1) of first AOI structure 908A, and another N-region coupled to ground (VSS). Further, from left-to-right, the second AOI layer includes a top P-layer with a P-region coupled to supply voltage (VDD), a gate region coupled to node (A1) of first AOI structure 908A, a P-region coupled to node (p0) of first AOI structure 908A, a gate region coupled to node (B1) of first AOI structure 908A, a P-region coupled to node (Y) of first AOI structure 908A, a gate region coupled to node (B0) of first AOI structure 908A, another P-region coupled to node (p0) of first AOI structure 908A, a gate region coupled to node (A0) of first AOI structure 908A, and another P-region coupled to supply voltage (VDD).

In some scenarios, the multi-layer AOI architecture 904B may have a multi-layered N-over-P-over-P-over-N(NPPN) multi-transistor stack configuration 918B. In this instance, as shown in FIG. 9B, the first AOI layer (or bottom layer) may have a first 2-stack device arranged in the P-over-N (PN) multi-transistor stack configuration, and the second AOI layer (or top layer) may have a second 2-stack device arranged in the N-over-P (NP) multi-transistor stack configuration. Further, in some instances, when the multiple layers are combined, the top NP layer is disposed on the bottom (bot) PN layer so as to form the NPPN multi-transistor stack configuration 918B.

In some implementations, from left-to-right, the first AOI layer includes a bot N-layer with an N-region coupled to ground (VSS), a gate region coupled to node (C1) of second AOI structure 908B, an uncoupled (−) N-region, a gate region coupled to node (C0) of second AOI structure 908B, an N-region coupled to node (Z) of second AOI structure 908B, a gate region coupled to node (D0) of second AOI structure 908B, an uncoupled (−) N-region, a gate region coupled to node (D1) of second AOI structure 908B, and another N-region coupled to ground (VSS). Also, from left-to-right, the first AOI layer includes a bot P-layer with a P-region coupled to supply voltage (VDD), a gate region coupled to node (C1) of second AOI structure 908B, a P-region coupled to node (q0) of second AOI structure 908B, a gate region coupled to node (D1) of second AOI structure 908B, a P-region coupled to node (Z) of second AOI structure 908B, a gate region coupled to node (D0) of second AOI structure 908B, another P-region coupled to node (q0) of second AOI structure 908B, a gate region coupled to node (C0) of second AOI structure 908B, and another P-region coupled to supply voltage (VDD).

In some scenarios, from left-to-right, the second AOI layer includes a top P-layer with a P-region coupled to supply voltage (VDD), a gate region coupled to node (A1) of first AOI structure 908A, a P-region coupled to node (p0) of first AOI structure 908A, a gate region coupled to node (B1) of first AOI structure 908A, a P-region coupled to node (Y) of first AOI structure 908A, a gate region coupled to node (B0) of first AOI structure 908A, another P-region coupled to node (p0) of first AOI structure 908A, a gate region coupled to node (A0) of first AOI structure 908A, and another P-region coupled to supply voltage (VDD). Also, from left-to-right, the second AOI layer includes a top N-layer with an N-region coupled to ground (VSS), a gate region coupled to node (A1) of first AOI structure 908A, an uncoupled (−) N-region, a gate region coupled to node (A0) of first AOI structure 908A, an N-region coupled to node (Y) of first AOI structure 908A, a gate region coupled to node (B0) of first AOI structure 908A, an uncoupled (−) N-region, a gate region coupled to node (B1) of first AOI structure 908A, and another N-region coupled to ground (VSS).

In some scenarios, the multi-layer AOI architecture 904C may have a multi-layered P-over-N-over-P-over-N (PNPN) multi-transistor stack configuration 918C. In this instance, as shown in FIG. 9C, the first AOI layer (or bottom layer) may have a first 2-stack device arranged in the P-over-N (PN) multi-transistor stack configuration, and the second AOI layer (or top layer) may have a second 2-stack device arranged in the P-over-N (PN) multi-transistor stack configuration. Further, in some instances, when the multiple layers are combined, the top PN layer is disposed on the bottom (bot) PN layer so as to form the PNPN multi-transistor stack configuration 918C.

In some implementations, from left-to-right, the first AOI layer includes a bot N-layer with an N-region coupled to ground (VSS), a gate region coupled to node (C1) of second AOI structure 908B, an uncoupled (−) N-region, a gate region coupled to node (C0) of second AOI structure 908B, an N-region coupled to node (Z) of second AOI structure 908B, a gate region coupled to node (D0) of second AOI structure 908B, an uncoupled (−) N-region, a gate region coupled to node (D1) of second AOI structure 908B, and another N-region coupled to ground (VSS). Also, from left-to-right, the first AOI layer includes a bot P-layer with a P-region coupled to supply voltage (VDD), a gate region coupled to node (C1) of second AOI structure 908B, a P-region coupled to node (q0) of second AOI structure 908B, a gate region coupled to node (D1) of second AOI structure 908B, a P-region coupled to node (Z) of second AOI structure 908B, a gate region coupled to node (D0) of second AOI structure 908B, another P-region coupled to node (q0) of second AOI structure 908B, a gate region coupled to node (C0) of second AOI structure 908B, and another P-region coupled to supply voltage (VDD).

In some scenarios, from left-to-right, the second AOI layer includes a top N-layer with an N-region coupled to ground (VSS), a gate region coupled to node (A1) of first AOI structure 908A, an uncoupled (−) N-region, a gate region coupled to node (A0) of first AOI structure 908A, an N-region coupled to node (Y) of first AOI structure 908A, a gate region coupled to node (B0) of first AOI structure 908A, an uncoupled (−) N-region, a gate region coupled to node (B1) of first AOI structure 908A, and another N-region coupled to ground (VSS). Further, from left-to-right, the second AOI layer includes a top P-layer with a P-region coupled to supply voltage (VDD), a gate region coupled to node (A1) of first AOI structure 908A, a P-region coupled to node (p0) of first AOI structure 908A, a gate region coupled to node (B1) of first AOI structure 908A, a P-region coupled to node (Y) of first AOI structure 908A, a gate region coupled to node (B0) of first AOI structure 908A, another P-region coupled to node (p0) of first AOI structure 908A, a gate region coupled to node (A0) of first AOI structure 908A, and another P-region coupled to supply voltage (VDD).

In some scenarios, the multi-layer AOI architecture 904C may have a multi-layered N-over-P-over-N-over-P (NPNP) multi-transistor stack configuration 918D. In this instance, as shown in FIG. 9C, the first AOI layer (or bottom layer) may have a first 2-stack device arranged in the N-over-P (NP) multi-transistor stack configuration, and the second AOI layer (or top layer) may have a second 2-stack device arranged in the N-over-P (NP) multi-transistor stack configuration. Further, in some instances, when the multiple layers are combined, the top NP layer is disposed on the bottom (bot) NP layer so as to form the NPNP multi-transistor stack configuration 918D.

In some implementations, from left-to-right, the first AOI layer includes a bot P-layer with a P-region coupled to supply voltage (VDD), a gate region coupled to node (C1) of second AOI structure 908B, a P-region coupled to node (q0) of second AOI structure 908B, a gate region coupled to node (D1) of second AOI structure 908B, a P-region coupled to node (Z) of second AOI structure 908B, a gate region coupled to node (D0) of second AOI structure 908B, another P-region coupled to node (q0) of second AOI structure 908B, a gate region coupled to node (C0) of second AOI structure 908B, and another P-region coupled to supply voltage (VDD). Further, from left-to-right, the first AOI layer includes a bot N-layer with an N-region coupled to ground (VSS), a gate region coupled to node (C1) of second AOI structure 908B, an uncoupled (−) N-region, a gate region coupled to node (C0) of second AOI structure 908B, an N-region coupled to node (Z) of second AOI structure 908B, a gate region coupled to node (D0) of second AOI structure 908B, an uncoupled (−) N-region, a gate region coupled to node (D1) of second AOI structure 908B, and another N-region coupled to ground (VSS).

In some scenarios, from left-to-right, the second AOI layer includes a top P-layer with a P-region coupled to supply voltage (VDD), a gate region coupled to node (A1) of first AOI structure 908A, a P-region coupled to node (p0) of first AOI structure 908A, a gate region coupled to node (B1) of first AOI structure 908A, a P-region coupled to node (Y) of first AOI structure 908A, a gate region coupled to node (B0) of first AOI structure 908A, another P-region coupled to node (p0) of first AOI structure 908A, a gate region coupled to node (A0) of first AOI structure 908A, and another P-region coupled to supply voltage (VDD). Also, from left-to-right, the second AOI layer includes a top N-layer with an N-region coupled to ground (VSS), a gate region coupled to node (A1) of first AOI structure 908A, an uncoupled (−) N-region, a gate region coupled to node (A0) of first AOI structure 908A, an N-region coupled to node (Y) of first AOI structure 908A, a gate region coupled to node (B0) of first AOI structure 908A, an uncoupled (−) N-region, a gate region coupled to node (B1) of first AOI structure 908A, and another N-region coupled to ground (VSS).

In various implementations, in reference to FIGS. 6A-6D, 7A-7B, 8A-8B and 9A-9C, the logic cell architecture may refer to a circuit having a multi-device stack structure formed with complementary field effect transistor (CFET) technology. The multi-device stack structure has P-type transistors and N-type transistors arranged vertically in a multi-transistor, e.g., four-transistor, or 4T stack configuration. Further, the multi-device stack structure may be formed in a single monolithic semiconductor die, and the P-type transistors and N-type transistors are formed within the single monolithic semiconductor die, and also, the logic cell architecture may refer to a three-dimensional (3D) monolithic circuit architecture. Also, logic cell architecture may refer to various types of logic cells (e.g., inverters, NAND gates, NOR gates and/or AOI gates) for use in logic based circuit applications, and further, the multi-transistor stack configuration may include a two or more device stack configurations of P-type transistors and N-type transistors. In some implementations, the multi-transistor stack may be a four-transistor (4T) stack configuration. Also, in some scenarios, the P-type transistors may refer to PFET devices, and the N-type transistors may refer to NFET devices. In some implementations, the four-transistor (4T) stack configuration may refer to a four-device stack of P-type transistors and N-type transistors that are arranged in a PNNP stack configuration, NPPN stack configuration, PNPN stack configuration, or NPNP stack configuration.

It should be intended that the subject matter of the claims not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Described herein are various implementations of a device having a multi-device stack structure for use in multi-layered circuit architectures. The multi-device stack structure may have P-type transistors and N-type transistors that are arranged vertically in a multi-transistor stack configuration.

Described herein are various implementations of a device. The device may have a multi-device stack structure for use in multi-bit memory architecture, such as, e.g., two-bit memory cell architecture, formed with complementary field effect transistor (CFET) technology. The multi-device stack structure may have P-type transistors and N-type transistors that are arranged vertically in a multi-transistor stack configuration.

Described herein are various implementations of a device. The device may have a multi-device stack structure for use in multi-bit logic architecture, such as, e.g., two-bit logic cell architecture, formed with complementary field effect transistor (CFET) technology. The multi-device stack structure may have P-type transistors and N-type transistors that are arranged vertically in a multi-transistor stack configuration.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various techniques described herein, other and further implementations may be devised in accordance with the disclosure herein, which may be determined by the claims that follow.

Although the subject matter has been described in language specific to structural features and/or methodological acts, it is to be understood that the subject matter defined in the appended claims is not necessarily limited to the specific features or acts described above. Rather, specific features and acts described above are disclosed as example forms of implementing the claims.

What is claimed is:

1. A device comprising:
a multi-device stack structure for use in multi-layered circuit architectures,
wherein the multi-device stack structure has P-type transistors and N-type transistors that are arranged vertically in a multi-transistor stack configuration.

2. The device of claim 1, wherein the multi-device stack structure is formed in a single semiconductor die, and wherein the P-type transistors and N-type transistors are formed within the single semiconductor die, and wherein the multi-layered circuit architecture is a three-dimensional (3D) circuit architecture.

3. The device of claim 1, wherein the multi-layered circuit architecture is used for at least one of bitcells, inverters, NAND gates, NOR gates and AND-OR-Invert (AOI) gates.

4. The device of claim 1, wherein the multi-transistor stack configuration includes a multi-device stack configuration of P-type transistors and N-type transistors arranged in at least one of a P-over-N-over-N-over-P (PNNP) stack configuration, a N-over-P-over-P-over-N(NPPN) stack configuration, a P-over-N-over-P-over-N (PNPN) stack configuration and a N-over-P-over-N-over-P (NPNP) stack configuration.

5. The device of claim 1, wherein the multi-transistor stack configuration includes a multi-device stack configuration of P-type transistors and N-type transistors, and wherein the P-type transistors are P-type field-effect transistors (PFETs), and wherein the N-type transistors are N-type field-effect transistors (NFETs).

6. A device comprising:
a multi-device stack structure for use in multi-bit memory architecture formed with complementary field effect transistor (CFET) technology,
wherein the multi-device stack structure has P-type transistors and N-type transistors that are arranged vertically in a multi-transistor stack configuration.

7. The device of claim 6, wherein the multi-device stack structure is formed in a single semiconductor die, and wherein the P-type transistors and N-type transistors are formed within the single semiconductor die, and wherein the multi-bit memory architecture is a three-dimensional (3D) circuit architecture.

8. The device of claim 6, wherein the multi-bit memory architecture comprises a multi-bit memory cell for use in random access memory (RAM) applications, and wherein the multi-transistor stack configuration includes at least one multi-device stack configuration of P-type transistors and N-type transistors, and wherein the P-type transistors are P-type field-effect transistors (PFETs), and wherein the N-type transistors are N-type field-effect transistors (NFETs).

9. The device of claim 6, wherein the multi-transistor stack configuration includes a multi-device stack configuration of P-type transistors and N-type transistors arranged in at least one of a P-over-N-over-N-over-P (PNNP) stack configuration, a N-over-P-over-P-over-N(NPPN) stack configuration, a P-over-N-over-P-over-N (PNPN) stack configuration, and a N-over-P-over-N-over-P (NPNP) stack configuration.

10. A device comprising:
a multi-device stack structure for use in multi-bit logic architecture formed with complementary field effect transistor (CFET) technology,
wherein the multi-device stack structure has P-type transistors and N-type transistors that are arranged vertically in a multi-transistor stack configuration.

11. The device of claim 10, wherein the multi-device stack structure is formed in a single monolithic semiconductor die, and wherein the P-type transistors and N-type transistors are formed within the single monolithic semiconductor die, and wherein the logic architecture is a three-dimensional (3D) circuit architecture.

12. The device of claim 10, wherein the multi-bit logic architecture comprises a multi-layer inverter standard cell for use in integrated circuits, and wherein the multi-transistor stack configuration includes a multi-device stack configuration of P-type transistors and N-type transistors, and wherein the P-type transistors are P-type field-effect transistors (PFETs), and wherein the N-type transistors are N-type field-effect transistors (NFETs).

13. The device of claim 10, wherein the multi-bit logic architecture comprises a multi-bit NAND gate for use in integrated circuits, and wherein the multi-transistor stack configuration includes a multi-device stack configuration of P-type transistors and N-type transistors, and wherein the P-type transistors are P-type field-effect transistors (PFETs), and wherein the N-type transistors are N-type field-effect transistors (NFETs).

14. The device of claim 10, wherein the multi-bit logic architecture comprises a multi-bit NOR gate for use in integrated circuits, and wherein the multi-transistor stack configuration includes a multi-device stack configuration of P-type transistors and N-type transistors, and wherein the P-type transistors are P-type field-effect transistors (PFETs), and wherein the N-type transistors are N-type field-effect transistors (NFETs).

15. The device of claim 10, wherein the multi-bit logic architecture comprises a multi-bit AND-OR-Invert gate for use in integrated circuits, and wherein the multi-transistor stack configuration includes a multi-device stack configuration of P-type transistors and N-type transistors, and wherein the P-type transistors are P-type field-effect transistors (PFETs), and wherein the N-type transistors are N-type field-effect transistors (NFETs).

16. The device of claim 10, wherein the multi-transistor stack configuration includes a multi-device stack configuration of P-type transistors and N-type transistors arranged in at least one of a P-over-N-over-N-over-P (PNNP) stack configuration, a N-over-P-over-P-over-N(NPPN) stack configuration, a P-over-N-over-P-over-N (PNPN) stack configuration, and a N-over-P-over-N-over-P (NPNP) stack configuration.
